(19) United States
(12) Patent Application Publication
(10) Pub. No.: US 2025/0331305 A1
(43) Pub. Date: Oct. 23, 2025

(54) THREE-DIMENSIONAL SEMICONDUCTOR DEVICE AND METHOD OF FABRICATING THE SAME

(71) Applicant: Samsung Electronics Co., Ltd., Suwon-si (KR)

(72) Inventors: DONGHOON HWANG, Suwon-si (KR); Jaeho JEON, Suwon-si (KR); HYOJIN KIM, Suwon-si (KR); Byungho MOON, Suwon-si (KR); KYOUNG-MI PARK, Suwon-si (KR); YOUNGJIN YANG, Suwon-si (KR)

(21) Appl. No.: 18/914,792

(22) Filed: Oct. 14, 2024

(30) Foreign Application Priority Data
Apr. 17, 2024 (KR) 10-2024-0051672

(51) Int. Cl. H01L 27/06; H01L 21/822; H01L 21/8238; H01L 27/092; H01L 29/06; H01L 29/08; H01L 29/417; H01L 29/423; H01L 29/66; H01L 29/775; H01L 29/786

(52) U.S. Cl. CPC H10D 88/00; H10D 30/014; H10D 30/43; H10D 30/6735; H10D 30/6757; H10D 62/121; H10D 62/151; H10D 64/258; H10D 84/0167; H10D 84/017; H10D 84/0181; H10D 84/0186; H10D 84/038; H10D 84/85; H10D 88/01

(57) ABSTRACT

A three-dimensional semiconductor device may include a lower active region on a substrate, including a lower channel pattern and a lower source/drain pattern connected thereto, an upper active region on the lower active region, including an upper channel pattern and an upper source/drain pattern connected thereto, a gate electrode disposed on the lower and upper channel patterns and extended in a first direction, and an insulating structure disposed at a side of the lower and upper active regions and extended in a second direction, the first and second directions being parallel to a top surface of the substrate. The insulating structure may include a first portion, adjacent to the lower active region, and a second portion, provided on the first portion and adjacent to the upper active region. A side surface of the insulating structure may have a stepwise structure at a boundary between the first and second portions.

### CROSS-REFERENCE TO RELATED APPLICATIONS

This U.S. non-provisional patent application claims priority under 35 U.S.C. § 119 to Korean Patent Application No. 10-2024-0051672, filed on Apr. 17, 2024, in the Korean Intellectual Property Office, the entire contents of which are hereby incorporated by reference.

### BACKGROUND OF THE INVENTION

The present disclosure relates to a three-dimensional semiconductor device and a method of fabricating the same, and in particular, to a three-dimensional semiconductor device including a field effect transistor and a method of fabricating the same.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

An embodiment of the inventive concept provides a three-dimensional semiconductor device with an increased integration density and improved electrical characteristics.

An embodiment of the inventive concept provides a method of fabricating a three-dimensional semiconductor device with an increased integration density and improved electrical characteristics.

According to an embodiment of the inventive concept, a three-dimensional semiconductor device may include a lower active region on a substrate, the lower active region including a lower channel pattern and a lower source/drain pattern connected to the lower channel pattern, an upper active region on the lower active region, the upper active region including an upper channel pattern and an upper source/drain pattern connected to the upper channel pattern, a gate electrode disposed on the lower and upper channel patterns and extended in a first direction, and an insulating structure disposed at a side of the lower and upper active regions and extended in a second direction, the first and second directions being parallel to a top surface of the substrate and crossing each other. The insulating structure may include a first portion, which is adjacent to the lower active region, and a second portion, which is provided on the first portion and is adjacent to the upper active region. A side surface of the insulating structure may have a stepwise structure at a boundary between the first portion and the second portion.

According to an embodiment of the inventive concept, a three-dimensional semiconductor device may include a lower active region on a substrate, the lower active region including a lower channel pattern and a lower source/drain pattern connected to the lower channel pattern, an upper active region stacked on the lower active region, the upper active region including an upper channel pattern and an upper source/drain pattern connected to the upper channel pattern, a gate electrode disposed on the lower and upper channel patterns and extended in a first direction, and an insulating structure disposed at a side of the lower and upper active regions and extended in a second direction, the first and second directions being parallel to a top surface of the substrate and crossing each other. The insulating structure may include a first portion, which is adjacent to the lower active region and a second portion, which is provided on the first portion and is adjacent to the upper active region. A side surface of the first portion may protrude relative to a side surface of the second portion in the first direction. The first portion may have a stepwise surface connecting the side surface of the first portion to the side surface of the second portion.

According to an embodiment of the inventive concept, a three-dimensional semiconductor device may include lower active regions spaced apart from each other in a first direction on a substrate, each of the lower active regions including lower channel patterns, which are spaced apart from each other in a second direction crossing the first direction, and lower source/drain patterns, which are connected to the lower channel patterns, upper active regions stacked on the lower active regions, respectively, each of the upper active regions including upper channel patterns, which are spaced apart from each other in the second direction, and upper source/drain patterns, which are connected to the upper channel patterns, gate electrodes disposed on the lower and upper channel patterns, respectively, the gate electrodes being extended in the first direction and being spaced apart from each other in the second direction, an insulating structure disposed between the lower active regions and the upper active regions and extended from the lower active regions to the upper active regions in a vertical direction, a cutting pattern, which is spaced apart from the insulating structure, with one of the lower active regions and one of the upper active regions interposed therebetween, in the first direction and is extended from the lower active regions to the upper active regions in the vertical direction, and a vertical via penetrating the cutting pattern in the vertical direction. The insulating structure may include a first portion, which is adjacent to the lower active region, and a second portion, which is provided on the first portion and is adjacent to the upper active region. A side surface of the insulating structure may have a ] boundary between the first and second portions, the boundary having a stepwise structure. The boundary may be located at a level that is higher than bottom surfaces of the upper source/drain patterns and is lower than top surfaces of the upper source/drain patterns.

### BRIEF DESCRIPTION OF THE DRAWINGS

FIG. 1 is a conceptual diagram illustrating a logic cell of a semiconductor device according to a comparative example.

FIG. 2 is a conceptual diagram illustrating a logic cell of a semiconductor device according to an embodiment of the inventive concept.

FIG. 3 is a plan view illustrating a three-dimensional semiconductor device according to an embodiment of the inventive concept.

FIGS. 4A to 4D are sectional views, which are respectively taken along lines A-A′, B-B′, C-C′, and D-D′ of FIG. 3.

FIG. 5 is an enlarged sectional view illustrating a portion ‘M’ of FIG. 4B.

FIGS. 6A to 6C are enlarged sectional views, each of which illustrates the portion ‘M’ of FIG. 4B.

FIGS. 7A to 19D are sectional views illustrating a method of fabricating a semiconductor device, according to an embodiment of the inventive concept.

FIGS. 20A and 20B are sectional views, which are respectively taken along lines A-A′ and B-B′ of FIG. 3.

### DETAILED DESCRIPTION

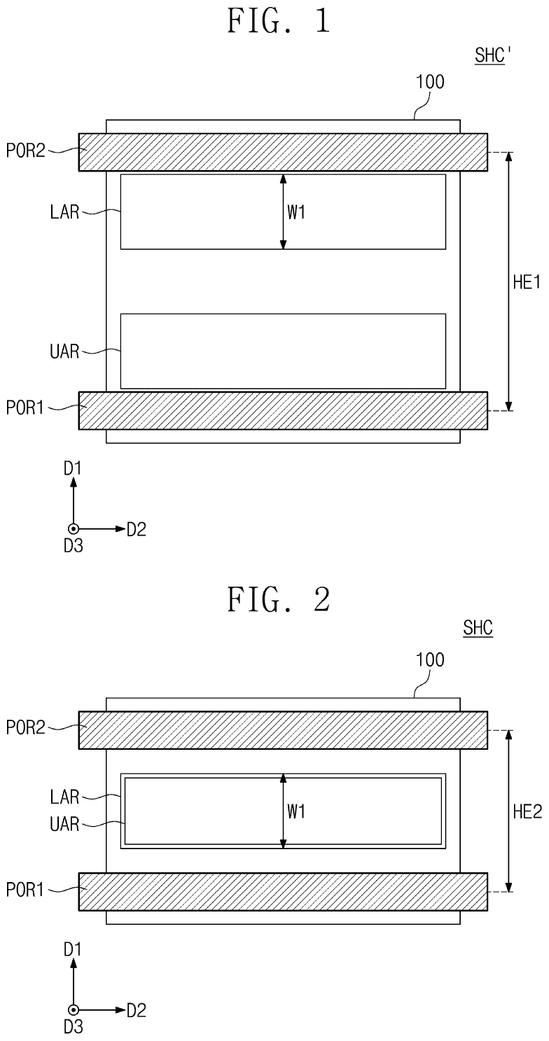

FIG. 1 is a conceptual diagram illustrating a logic cell of a semiconductor device according to a comparative example. In detail, FIG. 1 may illustrate a logic cell of a two-dimensional device according to the comparative example.

Referring to FIG. 1, a single height cell SHC′ may be provided. For example, a first power line POR1 and a second power line POR2 may be provided on a substrate 100. A drain voltage (e.g., a power voltage (VDD)) may be applied to one of the first and second power lines POR1 and POR2. A source voltage (e.g., a ground voltage (VSS)) may be applied to the other of the first and second power lines POR1 and POR2. In an embodiment, the source voltage may be applied to the first power line POR1, and the drain voltage may be applied to the second power line POR2.

The single height cell SHC′ may be defined between the first and second power lines POR1 and POR2. The single height cell SHC′ may include a lower active region LAR and an upper active region UAR. One of the lower and upper active regions LAR and UAR may be a PMOSFET region, and the other of the lower and upper active regions LAR and UAR may be an NMOSFET region. For example, the lower active region LAR may be an NMOSFET region, and the upper active region UAR may be a PMOSFET region. For example, the single height cell SHC′ may include a CMOS structure that is provided between the first and second power lines POR1 and POR2.

The semiconductor device according to the comparative example may be a two-dimensional device, in which the transistors of the front-end-of-line (FEOL) layer are two-dimensionally arranged. For example, an NMOSFET of the lower active region LAR may be spaced apart from a PMOSFET of the upper active region UAR in a first direction D1.

Each of the lower and upper active regions LAR and UAR may have a first width W1 in the first direction D1. In the comparative example, a length of the single height cell SHC′ in the first direction D1 may be defined as a first height HE1. The first height HE1 may be substantially equal to a distance (e.g., pitch) between the first and second power lines POR1 and POR2.

The single height cell SHC′ may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other. The logic device may be a CMOS device.

In the comparative example, since the single height cell SHC′ includes a two-dimensional device, the lower and upper active regions LAR and UAR may not be overlapped with each other in the plane of FIG. 1 (e.g., in the plane of the two-dimensional device), and may be spaced apart from each other in the first direction D1. Thus, the first height HE1 of the single height cell SHC′ should be defined to span both the lower and upper active regions LAR and UAR, which are spaced apart from each other in the first direction D1. As a result, the first height HE1 of the single height cell SHC′ in the comparative example may have a relatively increased value. For example, the single height cell SHC′ in the comparative example may have a relatively large area.

FIG. 2 is a conceptual diagram illustrating a logic cell of a semiconductor device according to an embodiment of the inventive concept. FIG. 2 illustrates a logic cell of a three-dimensional device according to an embodiment of the inventive concept.

Referring to FIG. 2, a single height cell SHC, which includes a three-dimensional device with stacked transistors, such as a three-dimensional (3D) field effect transistor (FET), complementary FET (CFET), and/or stacked FET (SFET), may be provided. In detail, the first power line POR1 and the second power line POR2 may be provided on the substrate 100. The single height cell SHC may be defined between the first power line POR1 and the second power line POR2.

The single height cell SHC may include the lower and upper active regions LAR and UAR. One of the lower and upper active regions LAR and UAR may be a PMOSFET region, and the other of the lower and upper active regions LAR and UAR may be an NMOSFET region. Accordingly, the single height cell SHC may be a CMOS device.

In the present embodiment, the semiconductor device may be a three-dimensional device, in which the transistors of the FEOL layer are vertically stacked. Accordingly, the semiconductor device may be a 3D FET, CFET, and/or SFET. The lower active region LAR serving as a bottom tier may be provided on the substrate 100, and the upper active region UAR serving as a top tier may be stacked on the lower active region LAR in a vertical direction (e.g., in a third direction D3). For example, the NMOSFET of the lower active region LAR may be provided on the substrate 100, and the PMOSFET of the upper active region UAR may be stacked on the NMOSFET. The lower and upper active regions LAR and UAR may be spaced apart from each other in the vertical direction (e.g., in the third direction D3).

Each of the lower and upper active regions LAR and UAR may have a first width W1 in the first direction D1. In the present embodiment, a length of the single height cell SHC in the first direction D1 may be defined as a second height HE2.

Since the single height cell SHC according to the present embodiment includes the three-dimensional device (e.g., the stacked transistors), the lower and upper active regions LAR and UAR may be overlapped with each other in the plane of FIG. 2 (e.g., in the plane of D1 and a second direction D2). Thus, the second height HE2 of the single height cell SHC may have a size spanning a single active region or may be only moderately larger than the first width W1. As a result, the second height HE2 of the single height cell SHC according to the present three-dimensional embodiment may be smaller than the first height HE1 of the single height cell SHC′ of FIG. 1 in a two-dimensional device, as described above. For example, the single height cell SHC in the present three-dimensional embodiment may have a relatively small area in the plane of FIG. 2 (e.g., in the D1-D2 plane). Accordingly, in the three-dimensional semiconductor device according to the present embodiment, an integration density of the device may be increased by reducing this area of the logic cell in the illustrated plane. However, adjacent cells of such a three-dimensional semiconductor device can be subject to a short circuit issue, which can be prevented by the disclosed embodiments, as described herein below.

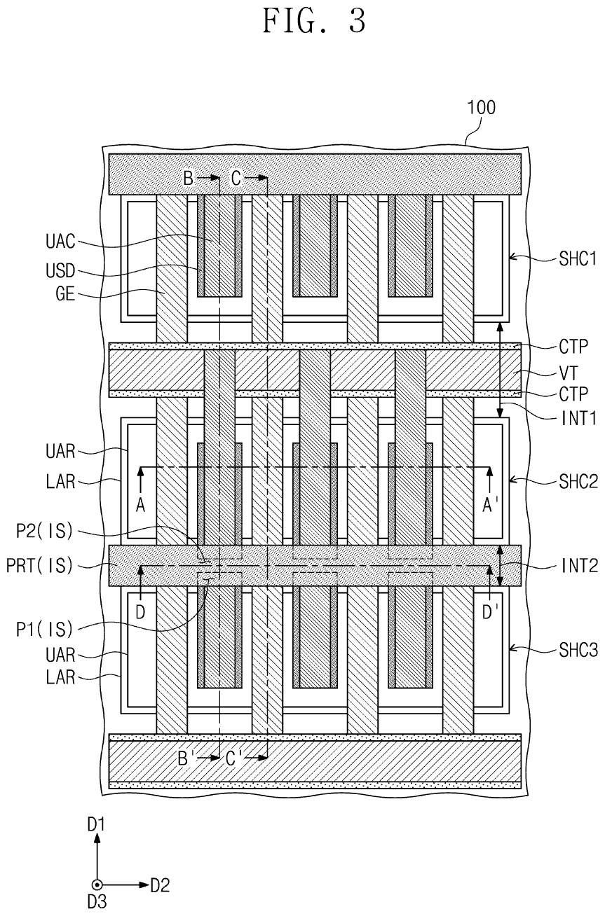

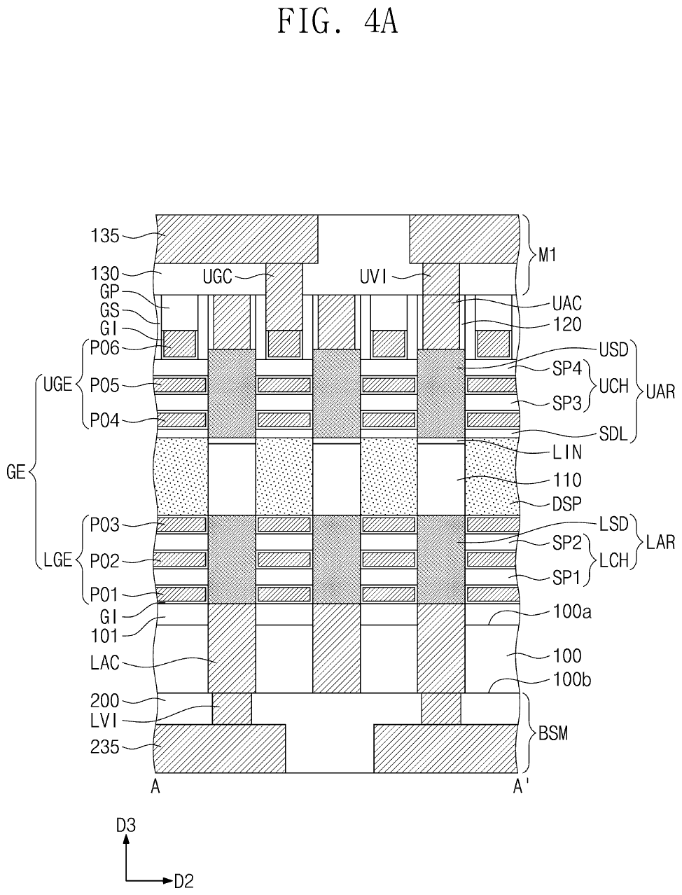

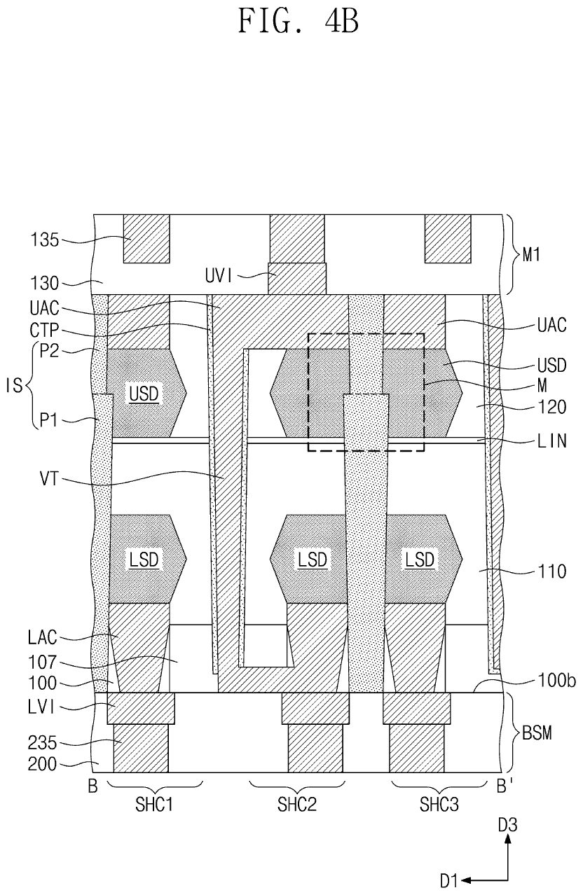

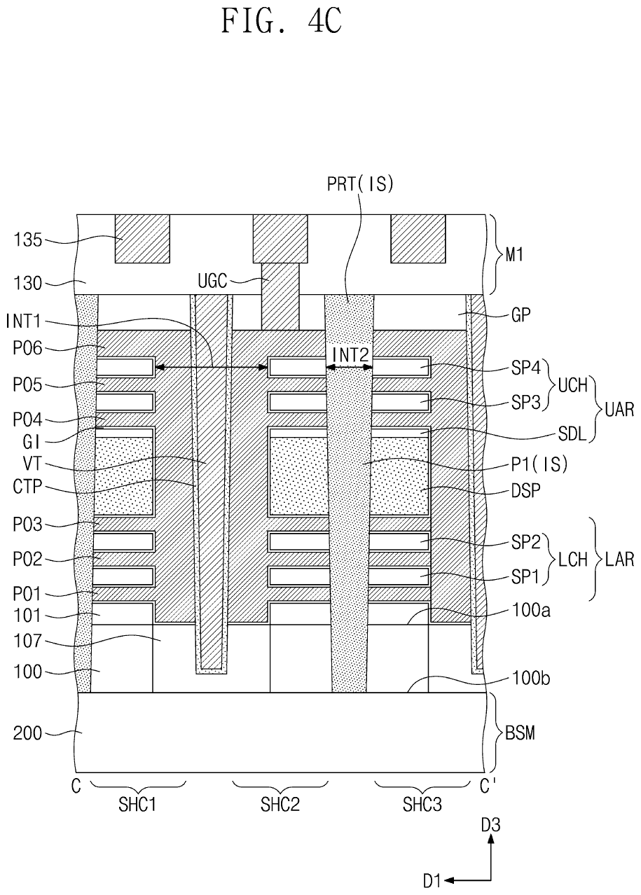

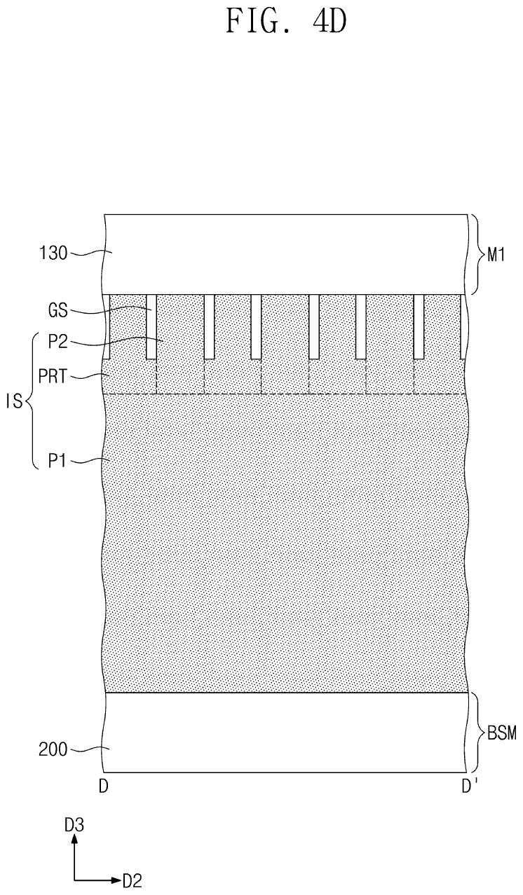

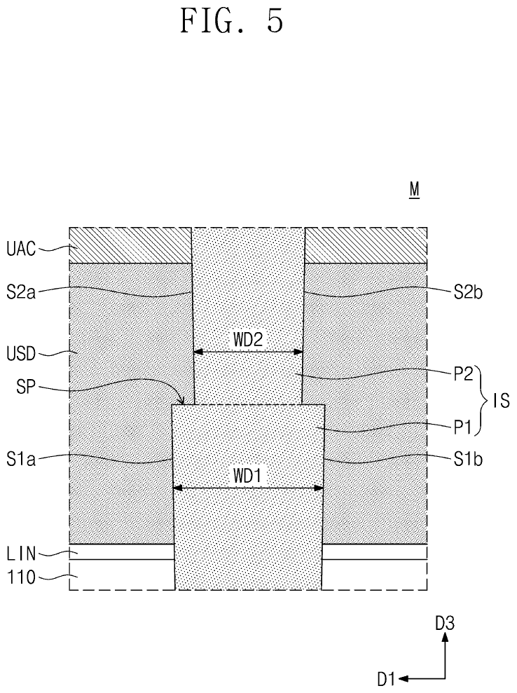

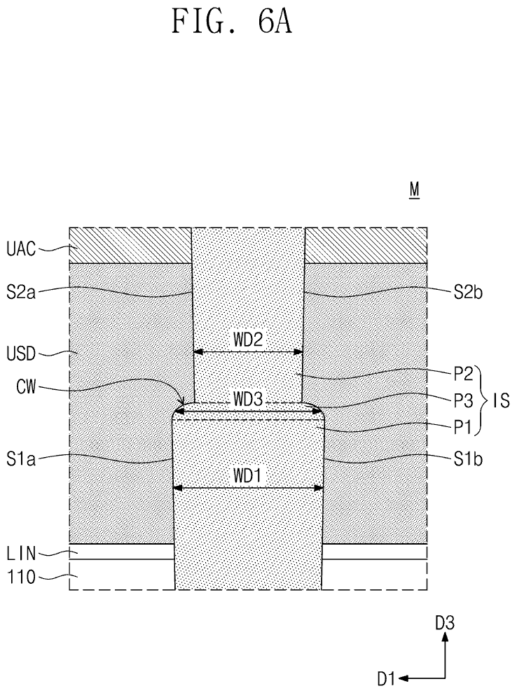

FIG. 3 is a plan view illustrating a three-dimensional semiconductor device according to an embodiment of the inventive concept. FIGS. 4A to 4D are sectional views, which are respectively taken along lines A-A′, B-B′, C-C′, and D-D′ of FIG. 3. The three-dimensional semiconductor device of FIGS. 3 and 4A to 4D may be a concrete example of the single height cell of FIG. 2.

Referring to FIG. 3 and FIGS. 4A to 4D, the single height cells SHC may be provided on the substrate 100. The substrate 100 may include a top surface 100a and a bottom surface 100b, which are opposite to each other. The top surface 100a may be a front surface of the substrate 100, and the bottom surface 100b may be a rear surface of the substrate 100. In an embodiment, the substrate 100 may be an insulating substrate, which is formed of or includes a silicon-based insulating material (e.g., silicon oxide and/or silicon nitride). In an embodiment, the substrate 100 may be a semiconductor substrate made of silicon, germanium, or silicon germanium.

A device isolation layer 107 may be disposed in the substrate 100. In the case where the single height cells SHC are spaced apart from each other by a relatively large distance, the device isolation layer 107 may be disposed between adjacent ones of the single height cells SHC. A cutting pattern CTP, which will be described below, may be provided to penetrate a portion of the device isolation layer 107. In an embodiment, the device isolation layer 107 may be formed of or include at least one of silicon-based insulating materials (e.g., silicon oxide, silicon oxynitride, and silicon nitride).

A first lower insulating layer 101 may be disposed on the substrate 100. When viewed in a plan view, the first lower insulating layer 101 may be overlapped with a lower channel pattern LCH and an upper channel pattern UCH, which will be described below. When viewed in a plan view, the first lower insulating layer 101 may not be overlapped with a lower source/drain pattern LSD and an upper source/drain pattern USD, which will be described below. The first lower insulating layer 101 may be formed of or include at least one of silicon-based insulating materials (e.g., silicon oxide) and/or semiconductor materials (e.g., Si or SiGe).

Each of the single height cells SHC may be a logic cell constituting a logic circuit. Each of the single height cells SHC may be a logic cell, for example a three-dimensional device previously described with reference to FIG. 2. The single height cells SHC may be arranged in the first direction D1. In the present specification, the first direction D1 and a second direction D2 may be parallel to the top surface 100a of the substrate 100 and may not be parallel to each other. The third direction D3 may be a vertical direction D3 that is perpendicular to the top surface 100a of the substrate 100. The first direction D1, the second direction D2, and the third direction D3 may not be parallel to each other.

A first single height cell SHC1, a second single height cell SHC2, and a third single height cell SHC3 may be spaced apart from each other in the first direction D1. The second single height cell SHC2 may be provided between the first single height cell SHC1 and the third single height cell SHC3.

The first and second single height cells SHC1 and SHC2 may be spaced apart from each other in the first direction D1 by a first distance INT1. The second single height cell SHC2 and the third single height cell SHC3 may be spaced apart from each other in the first direction D1 by a second distance INT2. The first distance INT1 may be larger than the second distance INT2. The second single height cell SHC2 may be closer to the third single height cell SHC3 than to the first single height cell SHC1.

Each of the single height cells SHC may include the lower active region LAR and the upper active region UAR, which are sequentially stacked on the substrate 100. One of the lower and upper active regions LAR and UAR may be a PMOSFET region, and the other of the lower and upper active regions LAR and UAR may be an NMOSFET region. The lower active region LAR may be provided as a bottom tier of the FEOL layer, and the upper active region UAR may be provided as a top tier of the FEOL layer. The NMOSFET and PMOSFET of the lower and upper active regions LAR and UAR may be vertically stacked to constitute transistors, which are three-dimensionally stacked. In an embodiment, the lower active region LAR may be an NMOSFET region, and the upper active region UAR may be a PMOSFET region.

Each of the lower and upper active regions LAR and UAR may be a bar- or line-shaped region that is extended in the second direction D2. One of a cutting pattern CTP or an insulating structure IS may be disposed between the single height cells SHC, which are adjacent to each other. In some examples, the insulating structure IS may function as a wall to separate the single height cells SHC (e.g., an NMOSFET and a PMOSFET) from each other, for example to form a CMOS device such as a 3D FET, CFET, and/or SFET. In some examples, insulating structure IS may additionally be structured like a wall, such as being vertically oriented, having opposing faces, and the like. For example, the insulating structure IS may be disposed between the lower active regions LAR and between the upper active regions UAR of adjacent single height cells SHC. The cutting pattern CTP may be spaced apart from the insulating structure IS in the first direction D1 with one of the lower active regions LAR interposed therebetween. The cutting pattern CTP may be spaced apart from the insulating structure IS in the first direction D1 with one of the upper active regions UAR interposed therebetween. The cutting pattern CTP and the insulating structure IS may be disposed alternately disposed between the single height cells SHC. For example, an insulating structure IT may be disposed at a side of the single height cells SHC, and the cutting pattern CTP may be disposed at an opposite side of the single height cells SHC. In other words, the insulating structure IS may be disposed at a side of the lower and upper active regions LAR and UAR, and the cutting pattern CTP may be disposed at an opposite side of the lower and upper active regions LAR and UAR. Thus, the single height cell SHC may have an asymmetric structure.

According to an embodiment of the inventive concept, the cutting pattern CTP may be disposed between the first and second single height cells SHC1 and SHC2. The insulating structure IS may be disposed between the second and third single height cells SHC2 and SHC3.

In the case where a distance between the single height cells SHC is relatively large, the cutting pattern CTP may be disposed. In the case where a distance between the single height cells SHC is relatively small, the insulating structure IS may be disposed.

The cutting pattern CTP may be provided to separate the single height cells SHC from each other. Adjacent ones of the single height cells SHC may be spaced apart from each other in the first direction D1 by the cutting pattern CTP. The cutting pattern CTP may be a bar- or line-shaped pattern extended in the second direction D2.

The insulating structure IS may be provided to separate the single height cells SHC from each other. The single height cells SHC, which are adjacent to each other, may be spaced apart from each other, in the first direction D1, by the insulating structure IS. The insulating structure IS may be a bar- or line-shaped structure that is extended in the second direction D2.

The lower active region LAR may include lower channel patterns LCH and lower source/drain patterns LSD. The lower channel pattern LCH may be interposed between a pair of the lower source/drain patterns LSD. The lower channel pattern LCH may connect the pair of the lower source/drain patterns LSD to each other. The lower channel pattern LCH may be spaced apart from the substrate 100 in the vertical direction D3, with the first lower insulating layer 101 interposed therebetween.

The cutting pattern CTP and the insulating structure IS may be alternatingly disposed between the lower channel patterns LCH, which are spaced apart from each other in the first direction D1. In the case where a distance between the lower channel patterns LCH, which are spaced apart from each other in the first direction D1, is relatively small, the insulating structure IS may be provided to separate the lower channel patterns LCH from each other. In the case where the distance between the lower channel patterns LCH, which are spaced apart from each other in the first direction D1, is relatively large, the cutting pattern CTP may be disposed between the lower channel patterns LCH. According to an embodiment of the inventive concept, the cutting pattern CTP may be disposed between the lower channel pattern LCH in the first single height cell SHC1 and the lower channel pattern LCH in the second single height cell SHC2. The insulating structure IS may be disposed between the lower channel pattern LCH in the second single height cell SHC2 and the lower channel pattern LCH in the third single height cell SHC3. The lower channel pattern LCH in the second single height cell SHC2 and the lower channel pattern LCH in the third single height cell SHC3 may be spaced apart from each other, in the first direction D1, by the insulating structure IS.

The lower channel pattern LCH may include a first semiconductor pattern SP1 and a second semiconductor pattern SP2, which are stacked to be spaced apart from each other in the vertical direction D3. Each of the first and second semiconductor patterns SP1 and SP2 may be formed of or include at least one of silicon (Si), germanium (Ge), or silicon germanium (SiGe). In an embodiment, each of the first and second semiconductor patterns SP1 and SP2 may be formed of or include crystalline silicon. Each of the first and second semiconductor patterns SP1 and SP2 may be a nanosheet. As an example, the lower channel pattern LCH may further include one or more semiconductor patterns, which are stacked and are spaced apart from the second semiconductor pattern SP2. The first semiconductor pattern SP1 may be the lowest semiconductor pattern.

The lower source/drain patterns LSD may be disposed on the substrate 100. Each of the lower source/drain patterns LSD may be an epitaxial pattern, which is formed by a selective epitaxial growth (SEG) process. In an embodiment, a top surface of the lower source/drain pattern LSD may be higher than a top surface of the second semiconductor pattern SP2 of the lower channel pattern LCH.

The lower source/drain patterns LSD may be doped with impurities to have a first conductivity type. The first conductivity type may be an n-type or a p-type. In the present embodiment, the first conductivity type may be an n-type. The lower source/drain patterns LSD may be formed of or include silicon (Si) and/or silicon germanium (SiGe).

A first interlayer insulating layer 110 may be disposed on the lower source/drain pattern LSD. The first interlayer insulating layer 110 may cover the lower source/drain patterns LSD. The first interlayer insulating layer 110 may cover the top surface 100a of the substrate 100 and the top surface of the device isolation layer 107. A top surface of the first interlayer insulating layer 110 may be located at a level higher than a top surface of the lower source/drain patterns LSD. In the present specification, the level may mean a distance measured from the top surface 100a of the substrate 100 in the vertical direction D3. A liner layer LIN may be disposed to conformally cover the top surface of the first interlayer insulating layer 110. The liner layer LIN may be interposed between the first interlayer insulating layer 110 and a second interlayer insulating layer 120, which will be described below.

A lower active contact LAC may be disposed below the lower source/drain pattern LSD. The lower active contact LAC may be electrically connected to the lower source/drain pattern LSD. The lower active contact LAC may be vertically extended from the bottom surface 100b of the substrate 100 to the top surface 100a. A top surface of the lower active contact LAC may be extended to a level higher than the top surface 100a of the substrate 100 and may be in direct contact with the lower source/drain pattern LSD. The lower active contact LAC may be formed of or include a metallic material that is selected from the group consisting of copper (Cu), aluminum (Al), ruthenium (Ru), cobalt (Co), tungsten (W), and molybdenum (Mo).

The upper active region UAR may be disposed on the first interlayer insulating layer 110 and the liner layer LIN. The upper active region UAR may include upper channel patterns UCH and upper source/drain patterns USD. The upper channel patterns UCH may be vertically overlapped with the lower channel patterns LCH, respectively. The upper source/drain patterns USD may be vertically overlapped with the lower source/drain patterns LSD, respectively. The upper channel pattern UCH may be interposed between a pair of the upper source/drain patterns USD. The upper channel pattern UCH may connect the paired upper source/drain patterns USD to each other.

The cutting pattern CTP and the insulating structure IS may be alternatingly disposed between the upper channel patterns UCH, which are spaced apart from each other in the first direction D1. In the case where a distance between the upper channel patterns UCH, which are spaced apart from each other in the first direction D1, is relatively small, the insulating structure IS may be provided to separate the upper channel patterns UCH from each other. In the case where the distance between the upper channel patterns UCH, which are spaced apart from each other in the first direction D1, is relatively large, the cutting pattern CTP may be disposed between the upper channel patterns UCH. According to an embodiment of the inventive concept, the cutting pattern CTP may be disposed between the upper channel pattern UCH in the first single height cell SHC1 and the upper channel pattern UCH in the second single height cell SHC2. The insulating structure IS may be disposed between the upper channel pattern UCH in the second single height cell SHC2 and the upper channel pattern UCH in the third single height cell SHC3. The upper channel pattern UCH in the second single height cell SHC2 may be spaced apart from the upper channel pattern UCH in the third single height cell SHC3, in the first direction D1, by the insulating structure IS.

The upper channel pattern UCH may include a third semiconductor pattern SP3 and a fourth semiconductor pattern SP4, which are stacked to be spaced apart from each other in the vertical direction D3. The third and fourth semiconductor patterns SP3 and SP4 of the upper channel pattern UCH may include the same semiconductor material as the first and second semiconductor patterns SP1 and SP2 of the lower channel pattern LCH. Each of the third and fourth semiconductor patterns SP3 and SP4 may be a nano-sheet. In an embodiment, the fourth semiconductor pattern SP4 may be the uppermost semiconductor pattern. In an embodiment, the upper channel pattern UCH may further include one or more semiconductor patterns that are stacked to be spaced apart from the fourth semiconductor pattern SP4.

At least one dummy channel pattern DSP may be interposed between the lower channel pattern LCH and the upper channel pattern UCH thereon. A seed layer SDL may be interposed between the dummy channel pattern DSP and the upper channel pattern UCH.

The dummy channel pattern DSP may be spaced apart from the lower and upper source/drain patterns LSD and USD. In other words, the dummy channel pattern DSP may not be connected to any source/drain pattern. The dummy channel pattern DSP may be formed of or include a semiconductor material (e.g., silicon (Si), germanium (Ge), or silicon germanium (SiGe)) or a silicon-based insulating material (e.g., silicon oxide or silicon nitride). In an embodiment, the dummy channel pattern DSP may be formed of or include the silicon-based insulating material.

The upper source/drain patterns USD may be disposed on a top surface of the liner layer LIN. Each of the upper source/drain patterns USD may be an epitaxial pattern, which is formed by a selective epitaxial growth (SEG) process. In an embodiment, a top surface of the upper source/drain pattern USD may be higher than a top surface of the fourth semiconductor pattern SP4 of the upper channel pattern UCH.

The upper source/drain patterns USD may be doped with impurities to have a second conductivity type. The second conductivity type may be different from the first conductivity type of the lower source/drain pattern LSD. The second conductivity type may be a p-type. The upper source/drain patterns USD may be formed of or include at least one of silicon germanium (SiGe) and/or silicon (Si).

A plurality of gate electrodes GE may be disposed on the single height cell SHC. In detail, the gate electrode GE may be disposed on the stacked lower and upper channel patterns LCH and UCH. When viewed in a plan view, the gate electrode GE may be a bar-shaped pattern, which is extended in the first direction D1. The gate electrode GE may be vertically overlapped with the stacked lower and upper channel patterns LCH and UCH.

The gate electrode GE may be extended from the substrate 100 to a gate capping pattern GP, which will be described below, in the vertical direction D3. The gate electrode GE may be extended from the top surface of the device isolation layer 107 and the top surface of the first lower insulating layer 101 to a gate capping pattern GP, which will be described below, in the vertical direction D3. The gate electrode GE may be extended from the lower channel pattern LCH of the lower active region LAR to the upper channel pattern UCH of the upper active region UAR in the third direction D3. The gate electrode GE may be extended from the lowermost semiconductor pattern (e.g., the first semiconductor pattern SP1) to the uppermost semiconductor pattern (e.g., the fourth semiconductor pattern SP4) in the third direction D3.

The gate electrode GE may be provided on a top surface, a bottom surface, and opposite side surfaces of each of the first to fourth semiconductor patterns SP1 to SP4. For example, the transistor according to the present embodiment may include a three-dimensional field effect transistor (e.g., a multi-bridge channel FET (MBCFET) or gate-all-around FET (GAAFET)) in which the gate electrode GE is provided to three-dimensionally surround the channel pattern.

The gate electrode GE may include a lower gate electrode LGE, which is provided in the bottom tier of the FEOL layer (e.g., the lower active region LAR), and an upper gate electrode UGE, which is provided in the top tier of the FEOL layer (e.g., the upper active region UAR). The lower and upper gate electrodes LGE and UGE may be vertically overlapped with each other. In an embodiment, the lower gate electrode LGE and the upper gate electrode UGE may be connected to each other. For example, the gate electrode GE according to the present embodiment may be a common gate electrode, in which the lower gate electrode LGE on the lower channel pattern LCH and the upper gate electrode UGE on the upper channel pattern UCH are connected to each other.

The lower gate electrode LGE may include a first inner electrode PO1 interposed between the first lower insulating layer 101 and the first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or the seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be respectively disposed on opposite side surfaces of the gate electrode GE. The paired gate spacers GS may be disposed on opposite side surfaces of the outer electrode PO6, respectively. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a gate capping pattern GP, which will be described below. The top surfaces of the gate spacers GS may be coplanar with a top surface of the insulating structure IS. The gate spacers GS may be formed of or include at least one of SiCN, SiCON, or SiN. In an embodiment, the gate spacers GS may be a multi-layered structure, which includes at least two different materials selected from SiCN, SiCON, and SiN.

The gate capping pattern GP may be disposed on a top surface of the gate electrode GE. The gate capping pattern GP may be extended along the gate electrode GE or in the first direction D1. In an embodiment, the gate capping pattern GP may be formed of or include at least one of SiON, SiCN, SiCON, or SiN.

A gate insulating layer GI may be interposed between the gate electrode GE and the first to fourth semiconductor patterns SP1-SP4. The gate insulating layer GI may be formed of or include at least one of silicon oxide, silicon oxynitride, and/or high-k dielectric materials. In an embodiment, the gate insulating layer GI may include a silicon oxide layer, which is formed to directly cover the semiconductor patterns SP1 to SP4, and a high-k dielectric layer, which is formed on the silicon oxide layer. In other words, the gate insulating layer GI may be a multi-layered structure including the silicon oxide layer and the high-k dielectric layer.

The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The lower gate electrode LGE may include a first work function metal pattern on the first and second semiconductor patterns SP1 and SP2. The upper gate electrode UGE may include a second work function metal pattern on the third and fourth semiconductor patterns SP3 and SP4. Each of the first and second work function metal patterns may be formed of a material, which contains at least one metallic element, which is selected from the group consisting of titanium (Ti), tantalum (Ta), aluminum (Al), tungsten (W), and molybdenum (Mo), and nitrogen (N). The first and second work function metal patterns may have different work functions from each other. The gate electrode GE may include at least one of low resistance metals (e.g., tungsten (W), ruthenium (Ru), aluminum (Al), titanium (Ti), and tantalum (Ta)) on the first and second work function metal patterns. In an embodiment, the outer electrode PO6 may include the second work function metal pattern as well as the low resistance metal.

The second interlayer insulating layer 120 may be disposed on the upper source drain pattern USD and the gate electrodes GE. The second interlayer insulating layer 120 may cover the upper source/drain patterns USD. The second interlayer insulating layer 120 may cover the top surface of the liner layer LIN. The top surface of the second interlayer insulating layer 120 may be coplanar with top surfaces of upper active contacts UAC, which will be described below. A third interlayer insulating layer 130 may cover the second interlayer insulating layer 120.

The upper active contacts UAC may be provided to penetrate the second interlayer insulating layer 120 and may be electrically connected to the upper source/drain patterns USD, respectively. The upper active contact UAC may be in direct contact with the upper source/drain pattern USD. The upper active contacts UAC may be spaced apart from each other, in the first direction D1, by the insulating structure IS.

An upper gate contact UGC may be provided to penetrate the third interlayer insulating layer 130 and the gate capping pattern GP and may be electrically connected to the upper gate electrode UGE. Each of the upper active contact UAC and the upper gate contact UGC may be formed of or include a metallic material that is selected from the group consisting of copper (Cu), aluminum (Al), ruthenium (Ru), cobalt (Co), tungsten (W), and molybdenum (Mo).

The cutting pattern CTP and the insulating structure IS may be alternately disposed between the gate electrodes GE, which are adjacent to each other in the first direction D1. The cutting pattern CTP and the insulating structure IS may separate the adjacent ones of the gate electrodes GE from each other. The adjacent ones of the gate electrodes GE may be spaced apart from each other in the first direction D1 by the cutting pattern CTP and the insulating structure IS. According to an embodiment of the inventive concept, the cutting pattern CTP may be provided to cut the gate electrode GE crossing the first and second single height cells SHC1 and SHC2 in the first direction D1. The insulating structure IS may also be provided to cut the gate electrode GE crossing the second and third single height cells SHC2 and SHC3 in the first direction D1.

The cutting pattern CTP may be extended from the lower active region LAR to the upper active region UAR in the vertical direction D3. The cutting pattern CTP may penetrate the gate capping pattern GP and the gate electrode GE and may penetrate a portion of the device isolation layer 107. A top surface of the cutting pattern CTP may be coplanar with a top surface of the gate capping pattern GP. A bottom surface of the cutting pattern CTP may be placed in the device isolation layer 107. The bottom surface of the cutting pattern CTP may be located at a level higher than a bottom surface of the insulating structure IS. The cutting pattern CTP may be a bar- or line-shaped pattern that is extended in the second direction D2. The cutting pattern CTP may be a single insulating layer or a plurality of insulating layers.

A vertical via VT may be disposed in the cutting pattern CTP. The vertical via VT may penetrate the cutting pattern CTP in the vertical direction D3. The cutting pattern CTP may cover opposite side surfaces of the vertical via VT. The cutting pattern CTP may be extended in the first direction D1 along a bottom surface of the vertical via VT. A top surface of the vertical via VT may be coplanar with the top surface of the cutting pattern CTP. The bottom surface of the vertical via VT may be located at a level higher than the bottom surface of the insulating structure IS. A width of the vertical via VT may increase as a distance from the bottom surface of the vertical via VT increases in the vertical direction D3.

The vertical via VT may connect the upper active contact UAC to the lower active contact LAC. The vertical via VT may be provided at a side of the upper and lower active contacts UAC and LAC. The upper active contact UAC may be extended in the first direction D1 and may be connected to an upper portion of the vertical via VT. The lower active contact LAC may be extended in the first direction D1 and may be connected to a lower portion of the vertical via VT.

The vertical via VT may include a metallic material. For example, the vertical via VT may be formed of or include at least one of copper (Cu), aluminum (Al), ruthenium (Ru), cobalt (Co), tungsten (W), or molybdenum (Mo).

The insulating structure IS may be a bar- or line-shaped pattern that is extended in the second direction D2. The insulating structure IS may include an insulating material. For example, the insulating structure IS may be formed of or include at least one of SiON, SiCN, SiCON, or SiN.

The insulating structure IS may be spaced apart from the vertical via VT and the cutting pattern CTP in the first direction D1, with one of the upper source/drain patterns USD interposed therebetween. The insulating structure IS may be spaced apart from the vertical via VT and the cutting pattern CTP in the first direction D1, with one of the lower source/drain patterns LSD interposed therebetween.

A level of a top surface of the insulating structure IS may be equal to or higher than a level of top surfaces of the gate electrodes GE. A level of the bottom surface of the insulating structure IS may be equal to or lower than a level of a bottom surface of the gate electrodes GE. The insulating structure IS may penetrate the gate electrode GE in the vertical direction D3.

The insulating structure IS may be extended in the vertical direction D3 to span the lower and upper active regions LAR and UAR. The insulating structure IS may be extended from the lower active contact LAC to the upper active contact UAC in the vertical direction D3.

The insulating structure IS may be interposed between adjacent ones of the upper source/drain patterns USD. The insulating structure IS may be interposed between adjacent ones of the lower source/drain patterns LSD. A side surface of the insulating structure IS may be in direct contact with the upper source/drain pattern USD and the lower source/drain pattern

LSD. The top surface of the insulating structure IS may be located at a level that is higher than the top surface of the upper source/drain pattern USD.

A level of the top surface of the insulating structure IS may be higher than or equal to a level of the top surface of the upper active contact UAC. The insulating structure IS may separate the adjacent ones of the upper active contacts UAC from each other. A level of the bottom surface of the insulating structure IS may be equal to or lower than a level of the bottom surface of the lower active contact LAC. A length of the insulating structure IS in the third direction D3 may be larger than a length of the cutting pattern CTP and a length of the vertical via VT.

The third interlayer insulating layer 130 may be disposed on the second interlayer insulating layer 120. A first metal layer M1 may be disposed in the third interlayer insulating layer 130. The first metal layer M1 may include upper interconnection lines 135. The first metal layer M1 may further include an upper via UVI. The upper via UVI may electrically connect the upper interconnection line UMI to the upper active contact UAC or the upper gate contact UGC. Each of the upper interconnection line 135 and the upper via UVI may be formed of or include a metallic material that is selected from the group consisting of copper (Cu), aluminum (Al), ruthenium (Ru), cobalt (Co), tungsten (W), and molybdenum (Mo).

Additional metal layers (e.g., M2, M3, M4, and so forth) may be stacked on the first metal layer M1. The first metal layer M1 and the additional metal layers (e.g., M2, M3, M4, and so forth) thereon may constitute a back-end-of-line (BEOL) layer of the semiconductor device. The additional metal layers (e.g., M2, M3, M4, and so forth) on the first metal layer M1 may include routing lines, which are used to connect the logic cells to each other.

A lower interlayer insulating layer 200 may be disposed below the bottom surface 100b of the substrate 100. A back-side metal layer BSM may be provided in the lower interlayer insulating layer 200. The back-side metal layer BSM may include lower interconnection lines 235. The back-side metal layer BSM may further include a lower via LVI. The lower via LVI may electrically connect the lower active contact LAC to the lower interconnection line 235. Each of the lower interconnection line 235 and the lower via LVI may be formed of or include a metallic material that is selected from the group consisting of copper (Cu), aluminum (Al), ruthenium (Ru), cobalt (Co), tungsten (W), and molybdenum (Mo).

Lower metal layers may be further stacked below the back-side metal layer BSM. In an embodiment, the lower metal layers may include a power delivery network. The power delivery network may include a wiring network, which is used to apply the source and drain voltages to the back-side metal layer BSM.

The source and drain voltages may be applied to the back-side metal layer BSM through the power delivery network. One of the source and drain voltages may be applied to the lower source/drain pattern LSD through the lower interconnection line 235, the lower via LVI, and the lower active contact LAC. The other of the source and drain voltages may be applied from the back-side metal layer BSM to the first metal layer M1 through a power tap cell. The voltage, which is applied to the first metal layer M1 through the power tap cell, may be applied to the upper source/drain pattern USD through the upper interconnection line 135, the upper via UVI, and the upper active contact UAC. The power tap cell may be interposed between the single height cells SHC, which are adjacent to each other.

FIG. 5 is an enlarged sectional view illustrating a portion ‘M’ of FIG. 4B. Hereinafter, the insulating structure IS according to an embodiment of the inventive concept will be described in more detail with reference to FIG. 5.

Referring to FIGS. 4D and 5, the insulating structure IS may include a first portion P1 and a second portion P2 and a protruding portion PRT, which are provided on the first portion P1. The first portion P1 may be extended from the bottom surface 100b of the substrate 100 to the upper active region UAR in the vertical direction D3. The first portion P1 may be provided to penetrate the substrate 100, the lower active region LAR, the first interlayer insulating layer 110, and the liner layer LIN and to penetrate a portion of the upper active region UAR. A top surface of the first portion P1 may be located at a level that is higher than a bottom surface of the upper source/drain pattern USD and is lower than the top surface of the upper source/drain pattern USD. The first portion P1 may be adjacent to the lower active region LAR.

The second portion P2 may be disposed on the first portion P1, which is placed between the upper source/drain patterns USD that are adjacent to each other in the first direction D1. A top surface of the second portion P2 may be coplanar with top surfaces of the second interlayer insulating layer 120, the gate capping pattern GP, the gate spacer GS, and the upper active contact UAC. The second portion P2 may be adjacent to the upper active region UAR. The second portion P2 may be spaced apart from the lower active region LAR. The second portion P2 may not be connected to the lower active region LAR. In an embodiment, a plurality of second portions P2 may be provided. The second portions P2 may be spaced apart from each other, in the second direction D2, on the first portion P1.

The protruding portion PRT may be disposed on the first portion P1, which is placed between the gate electrodes GE that are adjacent to each other in the first direction D1. A top surface of the protruding portion PRT may be coplanar with the top surfaces of the second portion P2, the second interlayer insulating layer 120, the gate capping pattern GP, the gate spacer GS, and the upper active contact UAC. In an embodiment, a plurality of protruding portions PRT may be provided. The protruding portions PRT may be spaced apart from each other, in the second direction D2, on the first portion P1. When viewed in a plan view, the protruding portions PRT may not be overlapped with the second portions P2. For example, the protruding portions PRT and the second portions P2 on the first portion P1 may be alternately disposed in the second direction D2.

The gate spacer GS may be interposed between the protruding portion PRT and the second portion P2. The protruding portion PRT may be extended along a bottom surface of the gate spacer GS and may be connected to the second portion P2.

An upper portion of the protruding portion PRT may be disposed between a pair of the gate spacers GS. A lower portion of the protruding portion PRT may be extended along bottom surfaces of the pair of the gate spacers GS. The protruding portion PRT may be extended from the top surface of the first portion P1 to the bottom surfaces of the paired gate spacers GS in the vertical direction D3 and may be extended to the bottom surface of the third interlayer insulating layer 130, in the vertical direction D3, through a region between the paired gate spacers GS.

Each of the first and second portions P1 and P2 may have side surfaces, which are opposite to each other in the first direction D1. The side surfaces of the first portion P1 and the side surfaces of the second portion P2 may form a stepwise (e.g., shaped like a tread or step) structure boundary between the first and second portions P1 and P2. The first portion P1 may include a first lower side surface S1a and a second lower side surface S1b. The second portion P2 may include a first upper side surface S2a and a second upper side surface S2b. The first lower side surface S1a may be spaced apart from the first upper side surface S2a in the first direction D1. The second lower side surface S1b may be spaced apart from the second upper side surface S2b in the first direction D1. In other words, the side surfaces of the first portion P1 may protrude relative to the side surfaces of the second portion P2 in the first direction D1.

The side surface of the insulating structure IS may have a stepwise (e.g., shaped like a tread or step) structure at the boundary between the first and second portions P1 and P2.

The first portion P1 may have a first width WD1 in the first direction D1. The second portion P2 may have a second width WD2 in the first direction D1. Each of the first and second widths WD1 and WD2 may increase as a distance from the bottom surface of the insulating structure IS increases in the vertical direction D3. The first width WD1 may have the largest value at the highest level of the first portion P1. The second width WD2 may have the largest value at the highest level of the second portion P2. The second width WD2 may have the smallest value at the lowest level of the second portion P2.

At the boundary between the first and second portions P1 and P2, the first width WD1 may be larger than the second width WD2. The greatest value of the first width WD1 may be greater than the smallest value of the second width WD2. In detail, the width of the first portion P1 at its highest level may be larger than the width of the second portion P2 at its lowest level. Accordingly, a width of the insulating structure IS may be discontinuously changed at a boundary between the first and second portions P1 and P2. The width of the insulating structure IS may be abruptly changed from the first width WD1 to the second width WD2, at the boundary between the first and second portions P1 and P2.

An outer side surface of the first portion P1 may include a stepwise (e.g., shaped like a step or a tread thereof) surface SP. The stepwise surface SP may be a top surface of the first portion P1 that is not covered with the second portion P2. The stepwise surface SP may be planarized horizontally, and may connect the side surfaces of the first portion P1 to the side surfaces of the second portion P2, at the boundary between. The stepwise surface SP may be located at the same level as the boundary between the first and second portions P1 and P2. The stepwise surface SP of the first portion P1 may be configured to change the width of the insulating structure IS from the first width WD1 to the second width WD2. Owing to the stepwise surface SP, the width of the insulating structure IS may be abruptly changed at the boundary between the first and second portions P1 and P2. The stepwise surface SP may include two portions, which are spaced apart from each other in the first direction D1 with the second portion P2 interposed therebetween.

The stepwise surface SP may be a horizontally planarized surface connecting the first lower side surface S1a to the first upper side surface S2a. The stepwise surface SP may be a surface connecting the second lower side surface S1b to the second upper side surface S2b.

The stepwise surface SP may be located at a level that is higher than the bottom surface of the upper source/drain pattern USD and is lower than the top surface of the upper source/drain pattern USD. In other words, the boundary between the first and second portions P1 and P2 may be located at a level that is higher than the bottom surface of the upper source/drain pattern USD and is lower than the top surface of the upper source/drain pattern USD.

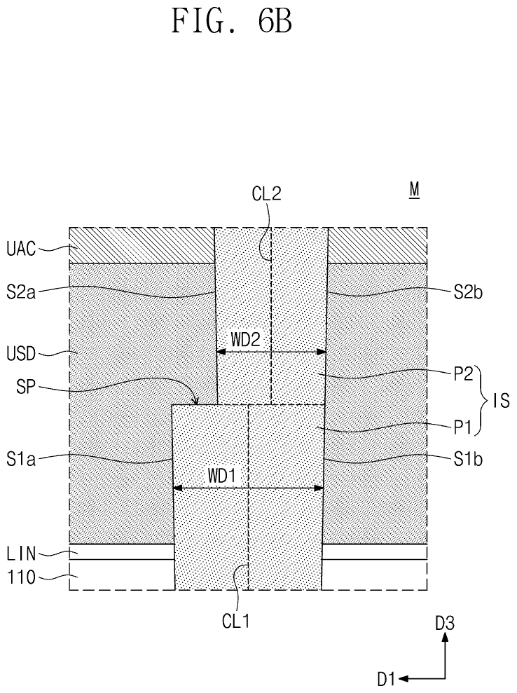

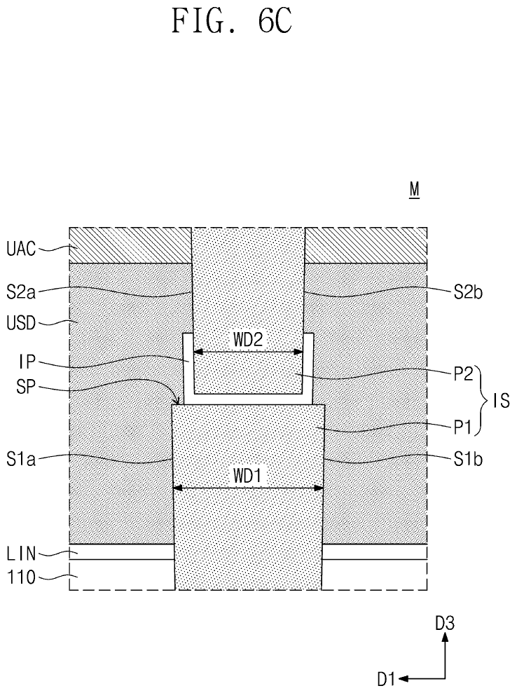

FIGS. 6A to 6C are enlarged sectional views, each of which illustrates the portion ‘M’ of FIG. 4B. For concise description, an element previously described with reference to FIG. 5 may be identified by the same reference number without repeating an overlapping description thereof.

Referring to FIG. 6A, a third portion P3 may be provided between the first and second portions P1 and P2. The third portion P3 may be located at a level that is higher than the bottom surface of the upper source/drain pattern USD and is lower than the top surface of the upper source/drain pattern USD. The third portion P3 may have a third width WD3 in the first direction D1. The third width WD3 may be smaller than the largest value of the first width WD1 and may be larger than the smallest value of the second width WD2. The third width WD3 may decrease as a distance from the first portion P1 increases in a direction toward the second portion P2. The third width WD3 may decrease as a distance from the first portion P1 increases and a distance to the second portion P2 decreases.

A side surface CW of the third portion P3 may have a curved surface. The side surface CW of the third portion P3 may be configured to change the width of the insulating structure IS from the first width WD1 to the second width WD2. The side surface CW of the third portion P3 may include two portions, which are spaced apart from each other in the first direction D1 with the second portion P2 interposed therebetween. Owing to the side surface CW of the third portion P3, in some examples, the width of the insulating structure IS may be gradually changed from the first width WD1 to the second width WD2.

Referring to FIG. 6B, a center line CL1 of the first portion P1 may be spaced apart from a center line CL2 of the second portion P2 in the first direction D1. The center line CL1 of the first portion P1 and the center line CL2 of the second portion P2 may be offset from each other in the first direction D1. For example, the first lower side surface S1a of the first portion P1 may protrude from the first upper side surface S2a of the second portion P2 in the first direction D1. The first lower side surface S1a of the first portion P1 and the first upper side surface S2a of the second portion P2 may be spaced apart from each other in the first direction D1. The second lower side surface S1b of the first portion P1 may be aligned to the second upper side surface S2b of the second portion P2 in the vertical direction D3. At a boundary between the first and second portions P1 and P2, the first lower side surface S1a and the first upper side surface S2a may form a stepwise structure. At the boundary between the first and second portions P1 and P2, the second lower side surface S1b and the second upper side surface S2b may not form a stepwise structure. The center line CL1 of the first portion P1 may be defined as an imaginary line passing through the center of the first portion P1 in the second direction D2, when viewed in a plan view. The center line CL2 of the second portion P2 may be defined as an imaginary line passing through the center of the second portion P2 in the second direction D2, when viewed in a plan view.

Referring to FIG. 6C, an insulating pattern IP may be interposed between the first and second portions P1 and P2. The insulating pattern IP may be in contact with the top surface of the first portion P1 and may be in contact with a bottom surface of the second portion P2. The insulating pattern IP may cover at least a portion of a side surface of the second portion P2. The insulating pattern IP may be extended from the bottom surface of the second portion P2, in the vertical direction D3, along the first and second upper side surfaces S2a and S2b. The insulating pattern IP may cover at least a portion of the top surface of the first portion P1. Owing to the insulating pattern IP, the second width WD2 of the second portion P2 may be smaller than the second width WD2 of FIG. 5. Thus, a distance between the upper active contacts UAC, which are adjacent to each other, may be reduced. As a result, the reliability and electrical characteristics of the three-dimensional semiconductor device may be improved.

The insulating pattern IP may include an oxide material. The insulating pattern IP may be a single oxide layer or a plurality of oxide layers. The insulating pattern IP may include a material having an etch selectivity different from the insulating structure IS. For example, the insulating structure IS may be formed of or include SiN, and the insulating pattern IP may be formed of or include SiON.

According to an embodiment of the inventive concept, the insulating structure IS may include two separate portions (e.g., the first and second portions P1 and P2). At the boundary between the first and second portions P1 and P2, the first width WD1 of the first portion P1 in the first direction D1 may be larger than the second width WD2 of the second portion P2 in the second direction D2. The stepwise surface SP may be formed between the first and second portions P1 and P2. This may be because, in a fabrication process to be described later, the first and second portions P1 and P2 of the insulating structure IS may be separately formed. Due to the insulating structure IS separating adjacent cells from each other, it may be possible to prevent a short circuit issue from occurring between the adjacent cells and to reduce an overall area of the logic cell. Accordingly, the disclosed semiconductor device and fabrication methods can improve over other semiconductor devices by preventing or reducing short circuits and/or reducing device size. In some examples, the stepwise surface SP of insulating structure IS may be formed via a two-step process, thereby preventing short circuit issues that may occur when the insulating structure is formed via a single process. In addition, in a process of forming the insulating structure IS to be described later, the first portion P1 may be formed before forming the source/drain patterns and the channel patterns, and in this case, it may be possible to improve the uniformity of the channel length. The second portion P2 may be formed after the formation of the upper source/drain patterns USD, and in this case, it may be possible to secure a patterning margin and prevent a skirt issue from occurring at intersections of several structures. In addition, since the second portion P2 is formed after the formation of the upper source/drain patterns USD, the upper source/drain patterns USD may be easily grown and may be formed to have an increased area. Accordingly, using the disclosed semiconductor device and fabrication methods, it may be possible to reduce a process difficulty in a subsequent process of forming a contact.

Furthermore, since the vertical via is formed in the cutting pattern, a width of the insulating structure may be reduced. As a result, according to an embodiment of the inventive concept, it may be possible to improve the electrical and reliability characteristics of the three-dimensional semiconductor device. In addition, it may be possible to reduce a cell height and to increase an integration density of the three-dimensional semiconductor device.

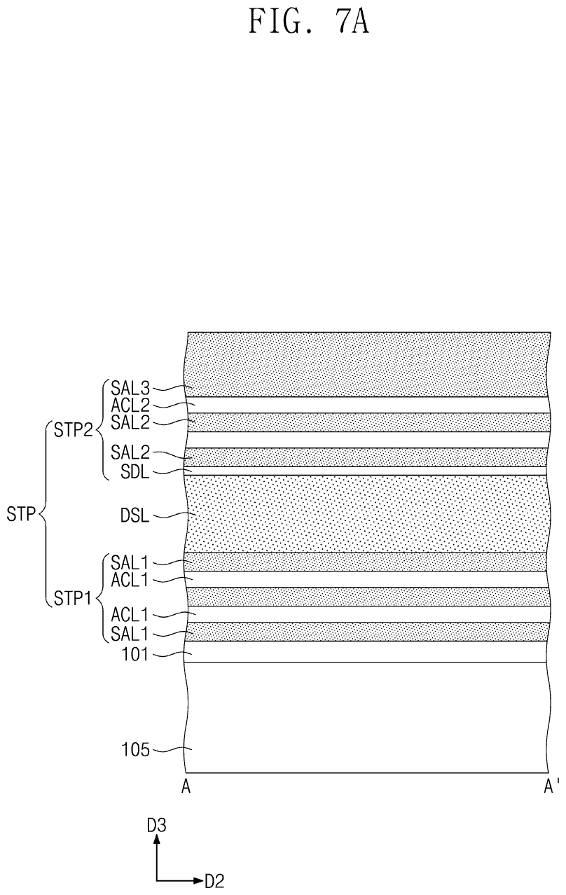

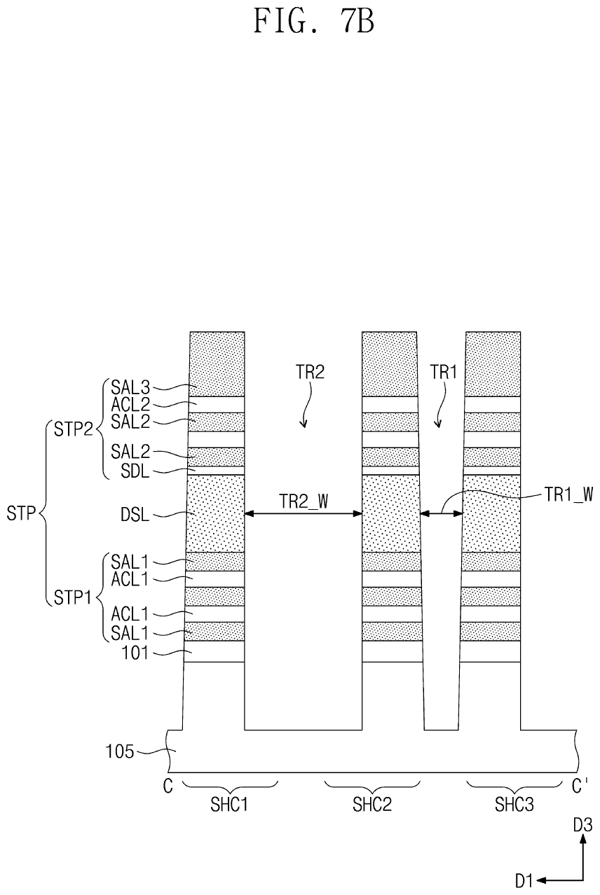

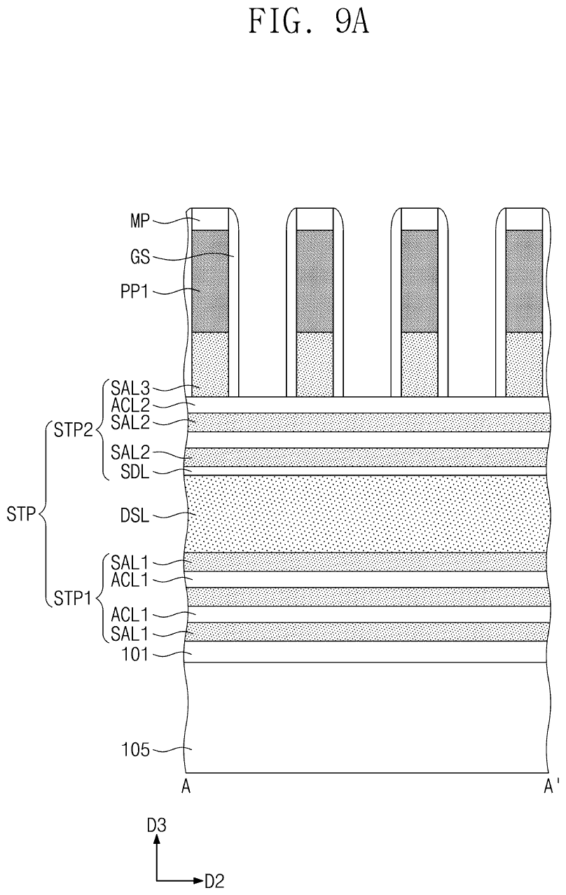

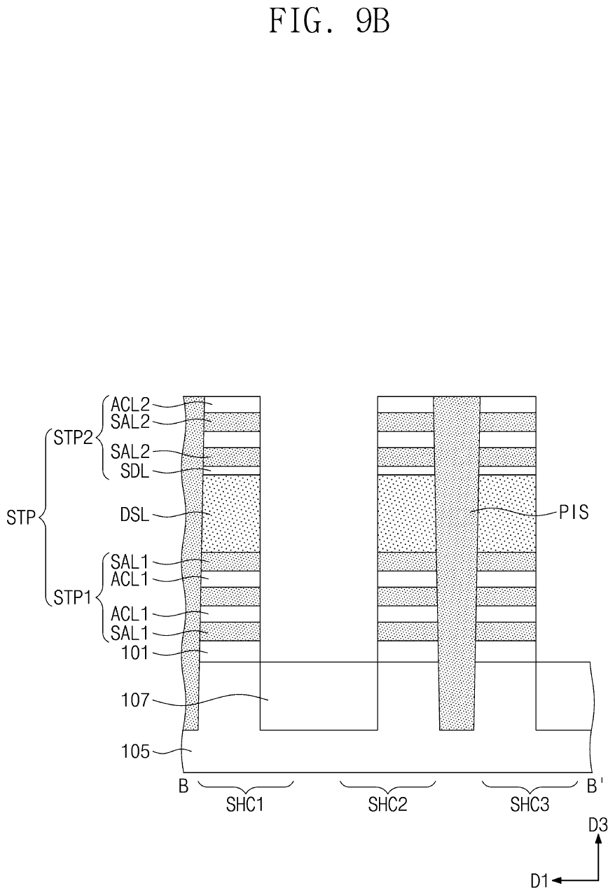

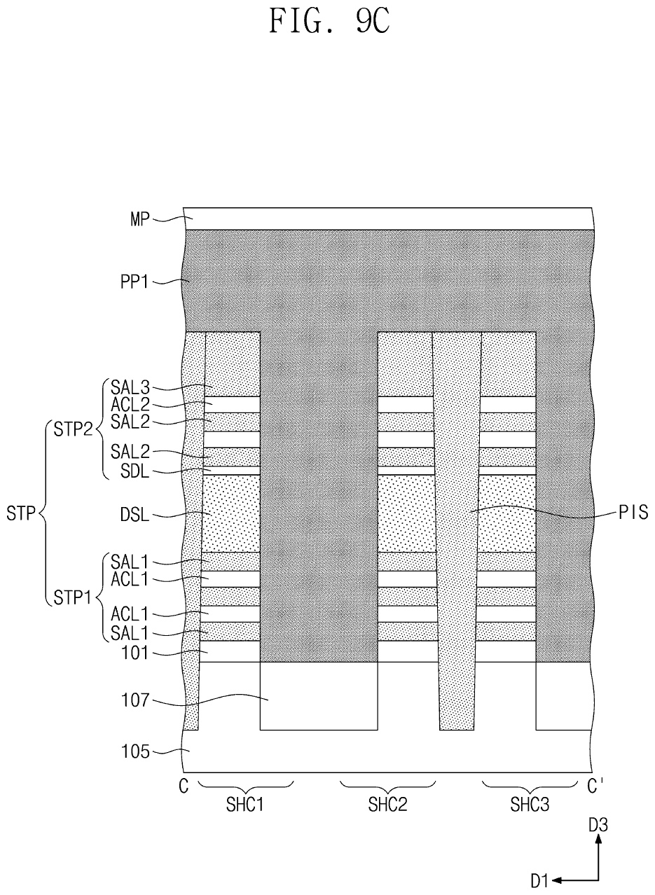

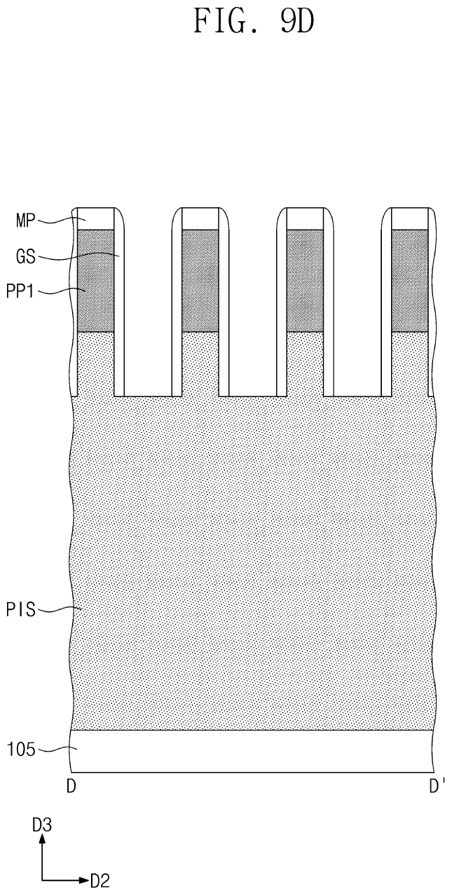

FIGS. 7A to 19D are sectional views illustrating a method of fabricating a semiconductor device, according to an embodiment of the inventive concept. In detail, FIGS. 7A, 9A, 10A, 11A, 12A, 13A, 14A, 18A, and 19A are sectional views corresponding to the line A-A′ of FIG. 3. FIGS. 9B, 10B, 11B, 12B, 13B, 14B, 16A, 17A, 18B, and 19B are sectional view corresponding to the line B-B′ of FIG. 3. FIGS. 7B, 8, 9C, 14C, 15B, 18C, and 19C are sectional views corresponding to the line C-C′ of FIG. 3. FIGS. 9D, 10C, 13C, 14D, 16B, 17B, 18D, and 19D are sectional views corresponding to the line D-D′ of FIG. 3.

Referring to FIGS. 7A and 7B, a semiconductor substrate 105 may be provided. The semiconductor substrate 105 may be formed of or include at least one of silicon (Si), germanium (Ge), or silicon-germanium (SiGe). For example, the semiconductor substrate 105 may be a single crystalline silicon wafer.

The first lower insulating layer 101 may be formed on the semiconductor substrate 105. The first lower insulating layer 101 may be formed of or include at least one of silicon-based insulating materials (e.g., silicon oxide) and/or semiconductor materials (Si or SiGe).

First sacrificial layers SAL1 and first active layers ACL1 may be alternatively stacked on the first lower insulating layer 101. The first sacrificial layers SAL1 and the first active layers ACL1 may be formed of or include at least one of silicon (Si), germanium (Ge), or silicon germanium (SiGe) and may be formed of different materials from each other. For example, the first sacrificial layers SAL1 may be formed of or include silicon germanium (SiGe), and the first active layers ACL1 may be formed of or include silicon (Si). A concentration of germanium (Ge) in each of the first sacrificial layers SAL1 may range from 10 at % to 30 at %.

A separation layer DSL may be formed on the uppermost one of the first sacrificial layers SAL1. In an embodiment, a thickness of the separation layer DSL may be larger than a thickness of the first sacrificial layer SAL1. The separation layer DSL may be formed of or include silicon (Si) or silicon germanium (SiGe). In the case where the separation layer DSL includes silicon germanium (SiGe), a germanium concentration of the separation layer DSL may be higher than a germanium concentration of the first sacrificial layer SAL1. For example, the germanium concentration of the separation layer DSL may range from 40 at % to 90 at %.

The seed layer SDL may be formed on the separation layer DSL. The seed layer SDL may include the same material as the first active layer ACL1. Second sacrificial layers SAL2 and second active layers ACL2 may be alternatively stacked on the seed layer SDL. Each of the second sacrificial layers SAL2 may be formed of or include the same material as the first sacrificial layer SAL1, and each of the second active layers ACL2 may be formed of or include the same material as the first active layer ACL1. The separation layer DSL may be interposed between the first sacrificial layer SAL1 and the seed layer SDL.

A third sacrificial layer SAL3 may be formed on the uppermost one of the second active layers ACL2. A thickness of the third sacrificial layer SAL3 may be larger than a thickness of the second active layer ACL2 and a thickness of the second sacrificial layer SAL2. The third sacrificial layer SAL3 may be formed of or include the same material as the second sacrificial layer SAL2.

A stacking pattern STP may be formed by patterning the first to third sacrificial layers SAL1, SAL2, and SAL3, the first and second active layers ACL1 and ACL2, the seed layer SDL, and the separation layer DSL. The formation of the stacking pattern STP may include forming a hard mask pattern on the third sacrificial layer SAL3, etching the layers SAL1, SAL2, SAL3, ACL1, ACL2, SDL, and DSL, which are stacked on the semiconductor substrate 105, using the hard mask pattern as an etch mask, and removing the hard mask pattern. During the formation of the stacking pattern STP, an upper portion of the semiconductor substrate 105 may be patterned to form trenches TR1 and TR2. The stacking pattern STP may be a bar- or line-shaped pattern that is extended in the second direction D2.

The stacking pattern STP may include a lower stacking pattern STP1 on the first lower insulating layer 101, an upper stacking pattern STP2 on the lower stacking pattern STP1, and the separation layer DSL between the lower and upper stacking patterns STP1 and STP2. The lower stacking pattern STP1 may include the first sacrificial layers SAL1 and the first active layers ACL1, which are alternately stacked. The upper stacking pattern STP2 may include the seed layer SDL and the second sacrificial and active layers SAL2 and ACL2, which are alternatingly stacked on the seed layer SDL. The upper stacking pattern STP2 may further include the third sacrificial layer SAL3 that is stacked on the uppermost one of the second active layers ACL2.

The trench may include a first trench TR1 and a second trench TR2. According to an embodiment of the inventive concept, the first trench TR1 may be formed between the second single height cell SHC2 and the third single height cell SHC3. The second trench TR2 may be formed between the first single height cell SHC1 and the second single height cell SHC2. A width TR2_W of the second trench TR2 in the first direction D1 may be larger than a width TR1_W of the first trench TR1 in the first direction D1. The width TR1_W of the first trench TR1 may increase as a distance from the semiconductor substrate 105 increases in the vertical direction D3. A width of the first trench TR1 may be larger at the uppermost level than at the lowermost width. A distance between the stacking pattern STP on the first single height cell SHC1 and the stacking pattern STP on the second single height cell SHC2 may be larger than a distance between the stacking pattern STP on the second single height cell SHC2 and the stacking pattern on the third single height cell SHC3.

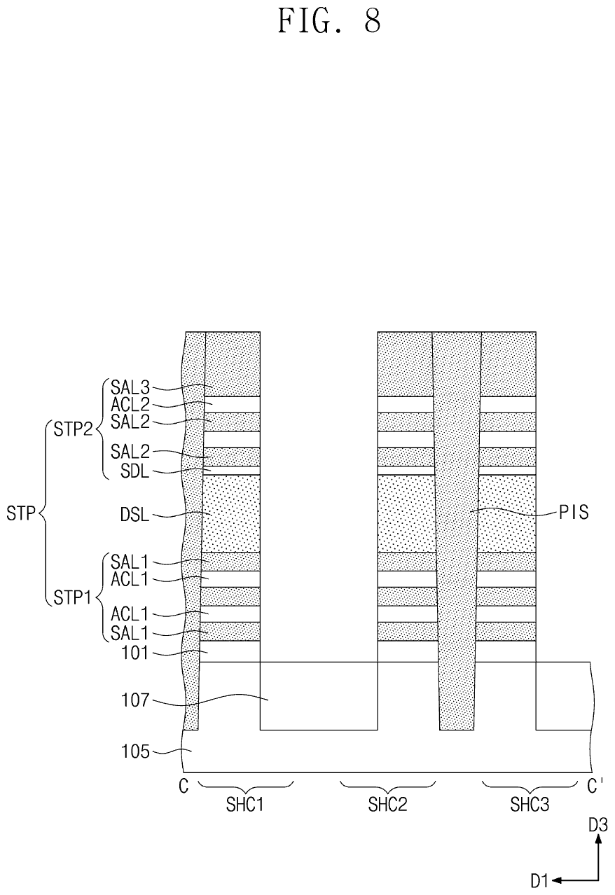

Referring to FIG. 8, a preliminary insulating structure PIS may be formed on the semiconductor substrate 105 to fill the first trench TR1. For example, the formation of the preliminary insulating structure PIS may include forming a mask layer (not shown) on the semiconductor substrate 105 to expose the first trench TR1, filling the first trench TR1 with an insulating material, recessing the insulating material to expose a top surface of the third sacrificial layer SAL3, and removing the mask layer. The recessing of the insulating material may be performed through a wet etching process.

The device isolation layer 107 may be formed on the semiconductor substrate 105 to fill a lower portion of the second trench TR2. In an embodiment, the formation of the device isolation layer 107 may include forming an insulating layer (not shown) on the semiconductor substrate 105 to cover the stacking patterns STP and recessing the insulating layer to expose the stacking patterns STP. The recessing of the insulating layer may be performed using a wet etching process. A top surface of the device isolation layer 107 may be coplanar with a top surface of the semiconductor substrate 105.

Referring to FIGS. 9A to 9D, a plurality of first sacrificial patterns PP1 may be formed to cross the stacking pattern STP. The first sacrificial patterns PP1 may be spaced apart from each other in the second direction D2. Each of the first sacrificial patterns PP1 may be a line-shaped pattern that is extended in the first direction D1. In an embodiment, the formation of the first sacrificial pattern PP1 may include forming a sacrificial layer (not shown) on the semiconductor substrate 105, forming a hard mask pattern MP on the sacrificial layer, and patterning the sacrificial layer using the hard mask pattern MP as an etch mask. The sacrificial layer may be formed of or include amorphous silicon and/or polysilicon. In an embodiment, the patterning process may be performed using an anisotropic etching process. A portion of the third sacrificial layer SAL3 and a portion of the preliminary insulating pattern PIS, which are not veiled by the hard mask pattern MP, may be also be etched during the patterning process. Thus, the preliminary insulating pattern PIS may have portions protruding in the vertical direction D3. The protruding portions may be spaced apart from each other in the second direction D2 and may be extended in the first direction D1. The protruding portions may be vertically overlapped with the first sacrificial patterns PP1.

A pair of the gate spacers GS may be respectively formed on opposite side surfaces of the first sacrificial pattern PP1. The gate spacers GS may be extended to cover side surfaces of the protruding portions of the preliminary insulating pattern PIS. In an embodiment, the formation of the gate spacers GS may include conformally forming a spacer layer (not shown) on the semiconductor substrate 105 and anisotropically etching the spacer layer. The spacer layer may cover the first sacrificial pattern PP1 and the hard mask pattern MP. For example, the spacer layer may be formed of or include at least one of SiCN, SiCON, or SiN.

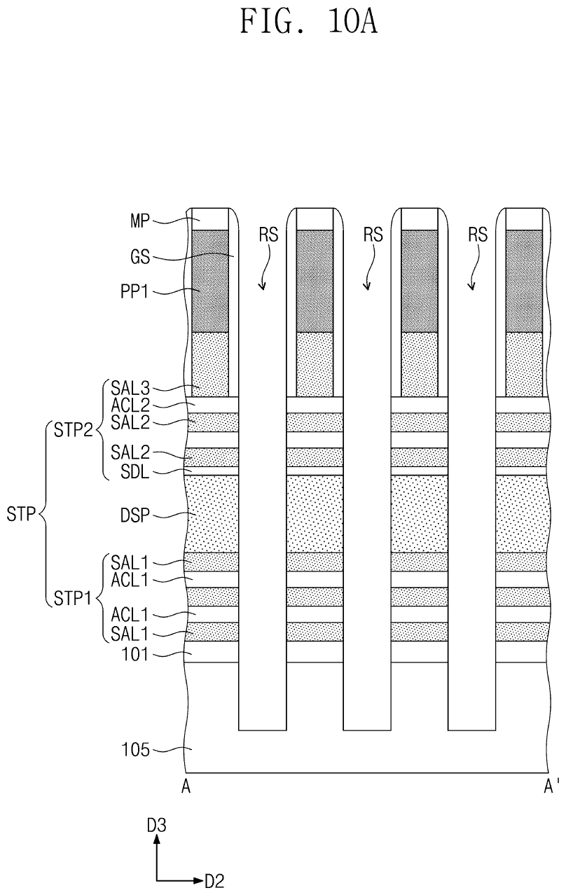

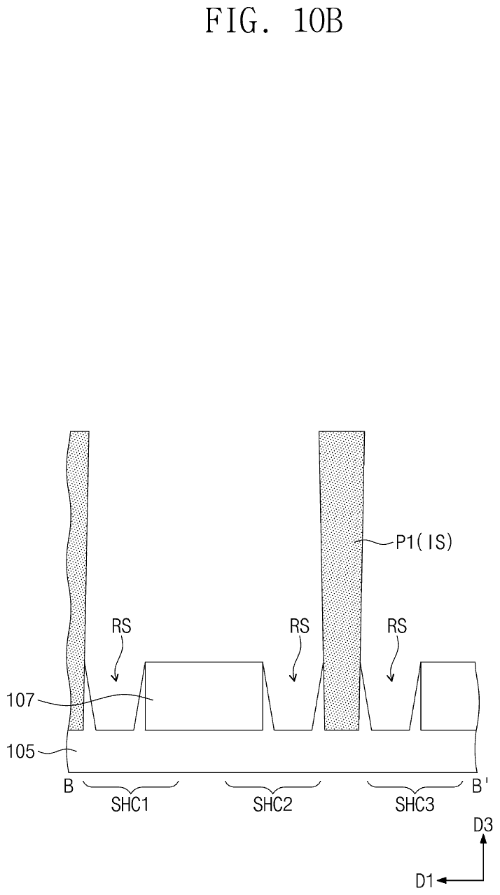

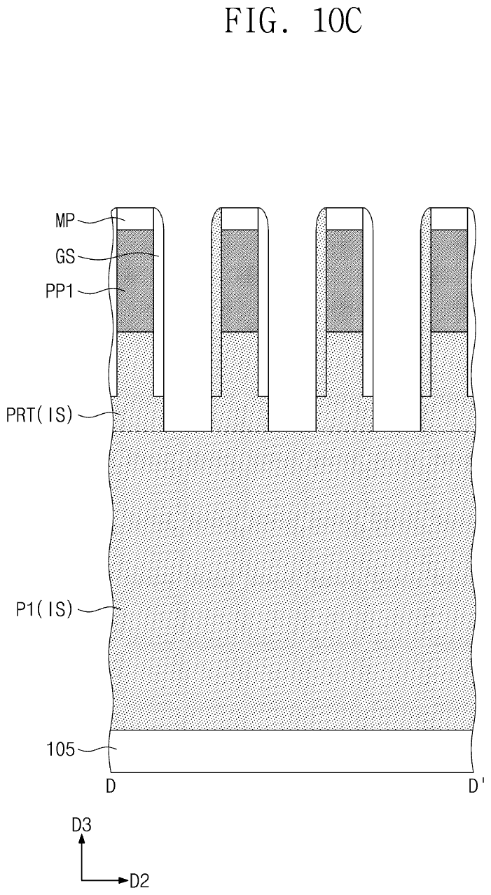

Referring to FIGS. 10A to 10C, an etching process may be performed on the stacking pattern STP using the gate spacers GS and the hard mask pattern MP as an etch mask. As a result of the etching process, a recess RS may be formed between the first sacrificial patterns PP1, which are adjacent to each other in the second direction D2. Due to the recess RS, the stacking pattern STP may be formed to have the shape of a vertical stick.

The etching process may be performed to partially remove an upper portion of the preliminary insulating structure PIS, and as a result, the first portion P1 and the protruding portion PRT on the first portion P1 may be formed. When viewed in a plan view, the protruding portion PRT may be vertically overlapped with the first sacrificial pattern PP1 and the gate spacers GS. The protruding portions PRT on the first portion P1 may be spaced apart from each other in the second direction D2. The top surface of the first portion P1 may be located at a level that is higher than a bottom surface of the upper stacking pattern STP2. The top surface of the first portion P1 may be located at a level that is lower than a top surface of the upper stacking pattern STP2.

In the case where the separation layer DSL includes silicon germanium (SiGe), the dummy channel pattern DSP may be formed by replacing the separation layer DSL with a silicon-based insulating material. For example, the separation layer DSL, which is exposed through the recess RS, may be selectively removed to form an empty region, and then, a silicon-based insulating material (e.g., silicon nitride) may be formed to fill the empty region. The top surface of the first portion P1 may be located at a level that is higher than a top surface of the dummy channel pattern DSP.

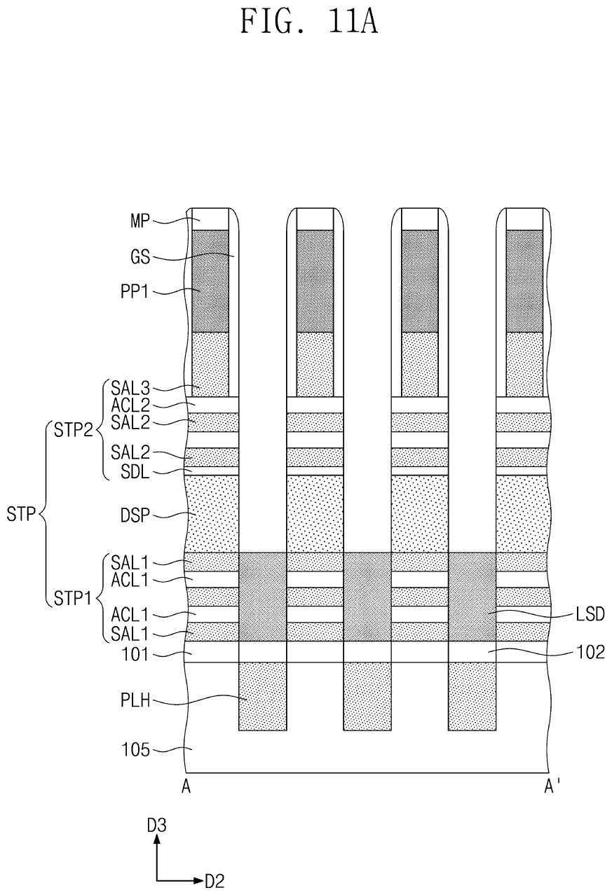

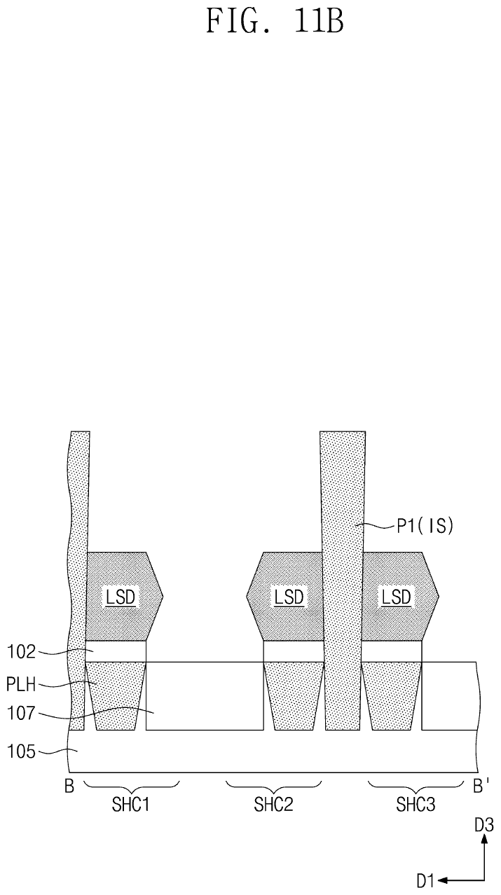

Referring to FIGS. 11A and 11B, sacrificial contact patterns PLH may be formed in the semiconductor substrate 105 that is exposed through the recess RS. The sacrificial contact patterns PLH may be formed to have a contact shape. The sacrificial contact patterns PLH may be arranged in the second direction D2. The sacrificial contact patterns PLH may include a material (e.g., silicon-germanium (SiGe)) having an etch selectivity with respect to the semiconductor substrate 105. The sacrificial contact patterns PLH may be formed by an epitaxial growth process. The recess RS may be formed to expose the sacrificial contact pattern PLH.

A second lower insulating layer 102 may be formed on the sacrificial contact pattern PLH. A top surface of the second lower insulating layer 102 may be coplanar with a top surface of the first lower insulating layer 101. The second lower insulating layer 102 may be formed of a silicon-based insulating material (e.g., silicon oxide, silicon oxynitride, or silicon nitride). In an embodiment, the second lower insulating layer 102 may be formed of the same material as the device isolation layer 107.

The lower source/drain pattern LSD may be formed on the second lower insulating layer 102. In detail, a first SEG process, in which an exposed side surface of the lower stacking pattern STP1 is used as a seed layer, may be performed to form the lower source/drain pattern LSD. The lower source/drain pattern LSD may be grown using the first active layers ACL1, which are exposed by the recess RS, as a seed layer. In an embodiment, the first SEG process may include a chemical vapor deposition (CVD) process or a molecular beam epitaxy (MBE) process.

As an example, impurities may be injected into the lower source/drain pattern LSD in an in-situ manner during the first SEG process. As another example, impurities may be injected into the lower source/drain pattern LSD, after the formation of the lower source/drain pattern LSD. The lower source/drain pattern LSD may be doped to have a first conductivity type (e.g., an n-type).

The lower source/drain pattern LSD may be formed to fully fill a space between a pair of lower stacking patterns STP1. For example, the first SEG process may be performed for a sufficient time until the lower source/drain pattern LSD is grown to fill a space between the paired lower stacking patterns STP1 and connect the paired lower stacking patterns STP1 to each other.

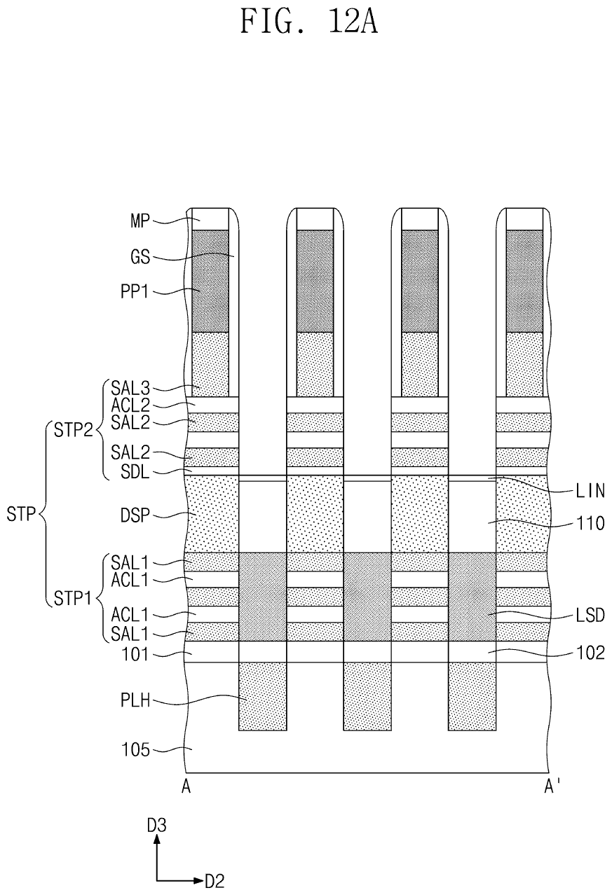

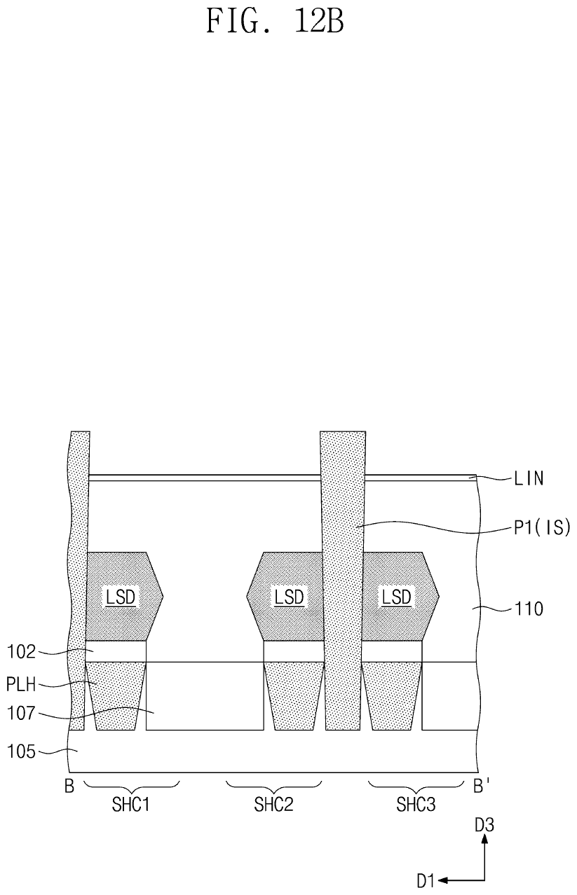

Referring to FIGS. 12A and 12B, the first interlayer insulating layer 110 may be formed to cover the lower source/drain pattern LSD. The first interlayer insulating layer 110 may cover a side surface of the upper stacking pattern STP2. Next, an upper portion of the first interlayer insulating layer 110 may be removed to re-expose the side surface of the upper stacking pattern STP2. The liner layer LIN may be formed to conformally cover the first interlayer insulating layer 110. The liner layer LIN may be a single insulating layer or a plurality of insulating layers.

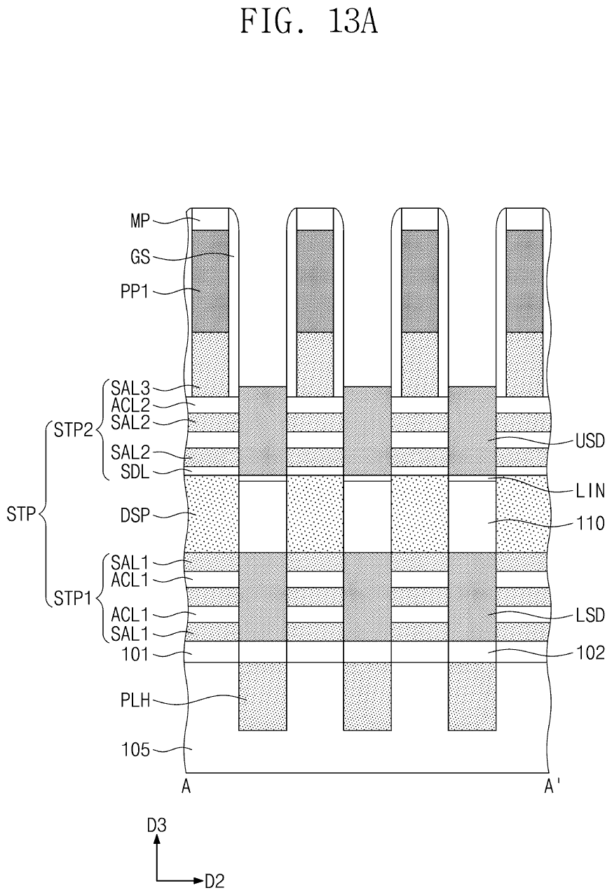

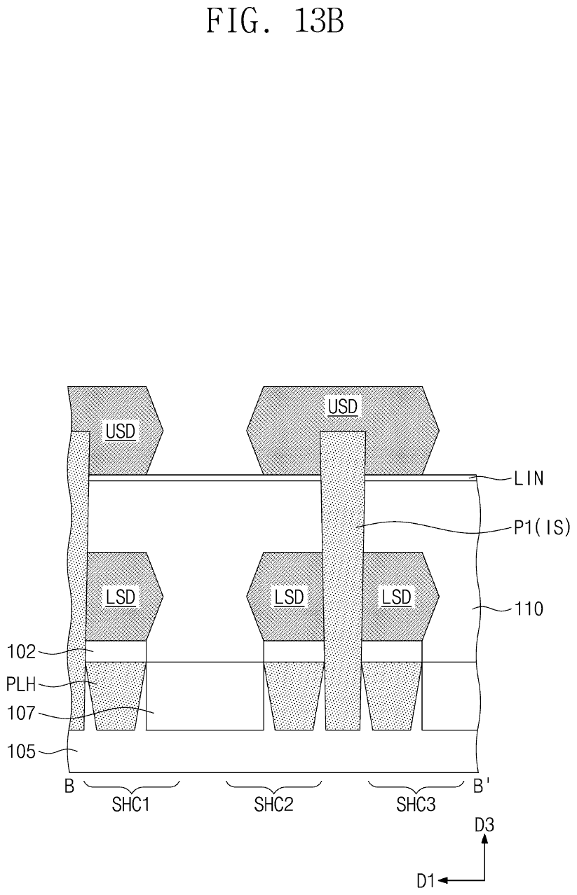

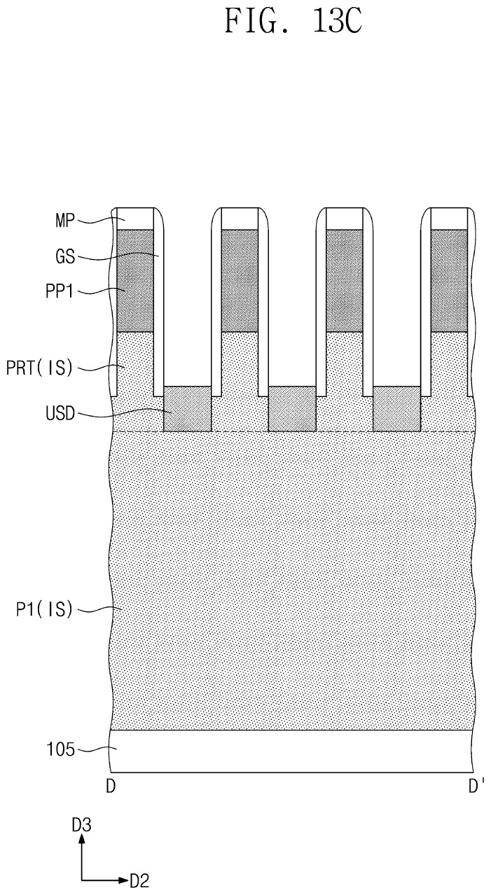

Referring to FIGS. 13A and 13B, the upper source/drain pattern USD may be formed on the exposed side surface of the upper stacking pattern STP2. The upper source/drain pattern USD may cover the top surface of the first portion P1. In detail, the upper source/drain pattern USD may be formed through a second SEG process using the exposed side surface of the upper stacking pattern STP2 as a seed layer. The upper source/drain pattern USD may be grown using the exposed second active layers ACL2 as a seed layer. The upper source/drain pattern USD may be doped to have the second conductivity type (e.g., p-type), which is different from the first conductivity type.

The second SEG process may also be performed for a sufficient time until the upper source/drain pattern USD is grown to fully fill a space between the paired upper stacking patterns STP2.

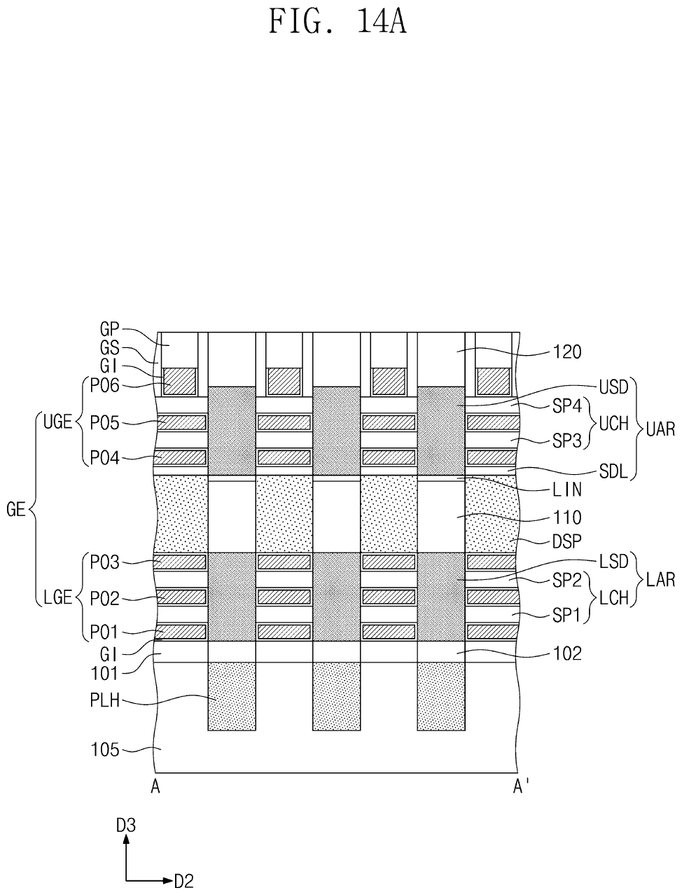

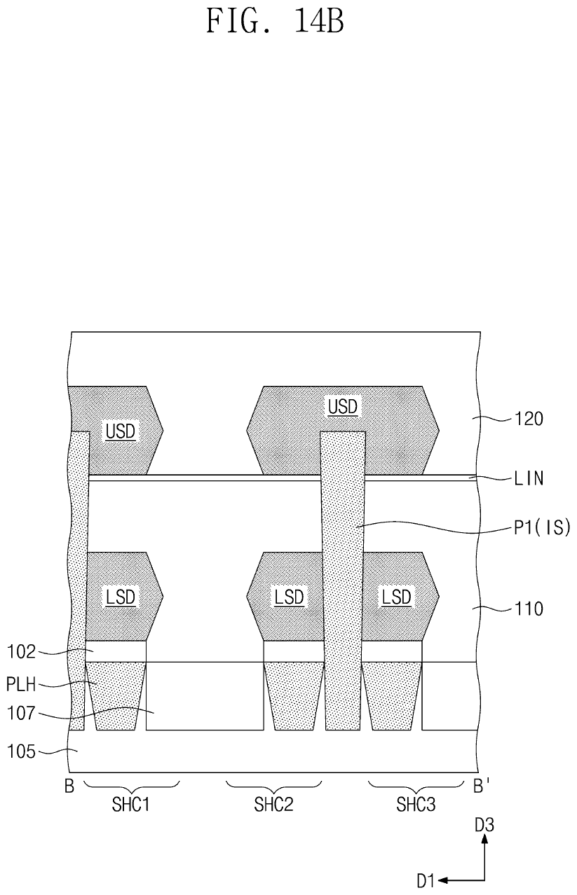

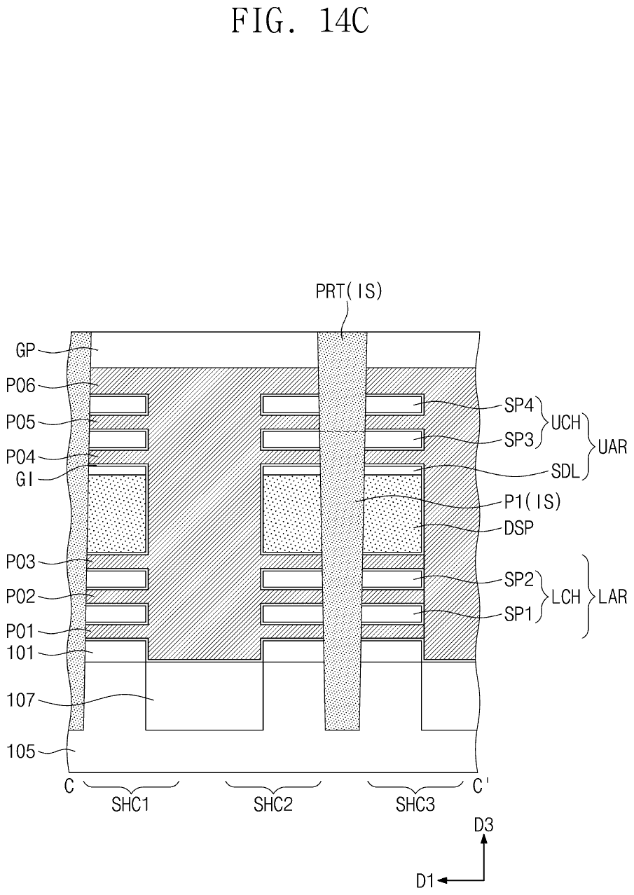

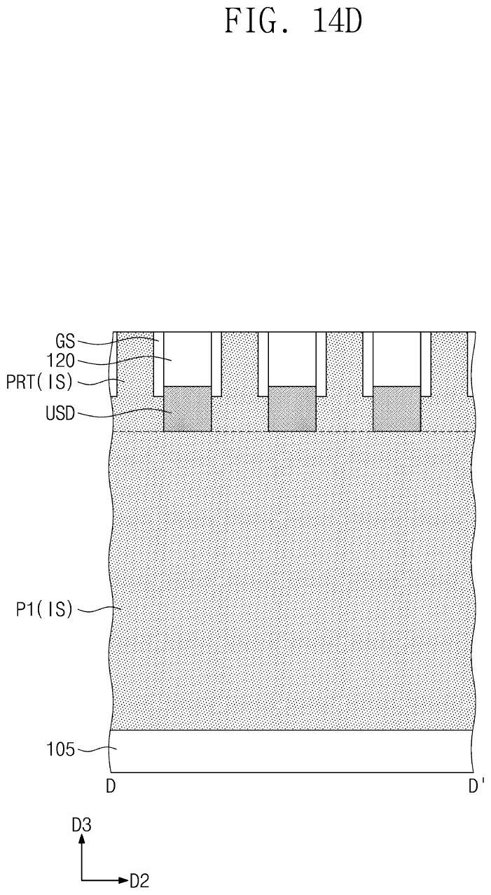

Referring to FIGS. 14A to 14D, the first active layers ACL1, which are interposed between the paired lower source/drain patterns LSD, may constitute the lower channel pattern LCH. For example, the first and second semiconductor patterns SP1 and SP2 of the lower channel pattern LCH may be formed from the first active layers ACL1. The lower channel patterns LCH and the lower source/drain patterns LSD may constitute the lower active region LAR serving as the bottom tier of the three-dimensional device. The second active layers ACL2, which are interposed between the paired upper source/drain patterns USD, may constitute the upper channel pattern UCH. For example, the third and fourth semiconductor patterns SP3 and SP4 of the upper channel pattern UCH may be formed from the second active layers ACL2. The upper channel patterns UCH and the upper source/drain patterns USD may constitute the upper active region UAR serving as the top tier of the three-dimensional device.

The second interlayer insulating layer 120 may be formed to cover the upper source/drain pattern USD. In an embodiment, the second interlayer insulating layer 120 may include a silicon oxide layer.

A planarization process may be performed on the second interlayer insulating layer 120 to expose the top surface of the first sacrificial pattern PP1. The planarization of the second interlayer insulating layer 120 may be performed using an etch-back process or a chemical mechanical polishing (CMP) process. The hard mask pattern MP on the first sacrificial pattern PP1 may be fully removed during the planarization process. As a result, the top surface of the second interlayer insulating layer 120 may be coplanar with the top surface of the first sacrificial pattern PP1 and the top surfaces of the gate spacers GS.

The exposed first sacrificial pattern PP1 may be selectively removed. The removal of the first sacrificial pattern PP1 may include a wet etching process using an etching solution capable of selectively etching polysilicon. Since the first sacrificial pattern PP1 is removed, the first to third sacrificial layers SAL1, SAL2, and SAL3 may be exposed.

An etching process, which is chosen to selectively etch the first to third sacrificial layers SAL1, SAL2, and SAL3, may be performed to leave the first to fourth semiconductor patterns SP1 to SP4 and the dummy channel pattern DSP and to remove only the first to third sacrificial layers SAL1, SAL2, and SAL3. The etching process may be chosen to have a high etch rate to silicon germanium. For example, the etching process may be chosen to have a high etch rate to a silicon germanium layer whose germanium concentration is higher than 10 at %.

The gate insulating layer GI may be conformally formed in an empty space, which is formed by removing the first sacrificial pattern PP1 and the first to third sacrificial layers SAL1, SAL2, and SAL3. The gate electrode GE may be formed on the gate insulating layer GI. The formation of the gate electrode GE may include forming first to fifth inner electrodes PO1-PO5 between the first to fourth semiconductor patterns SP1-SP4 and forming the outer electrode PO6 in an empty region formed by removing the third sacrificial layer SAL3 and the first sacrificial pattern PP1.

The gate electrode GE may be vertically recessed to have a reduced height. The gate capping pattern GP may be formed on the recessed gate electrode GE. A planarization process may be performed on the gate capping pattern GP such that a top surface of the gate capping pattern GP is coplanar with the top surface of the second interlayer insulating layer 120.

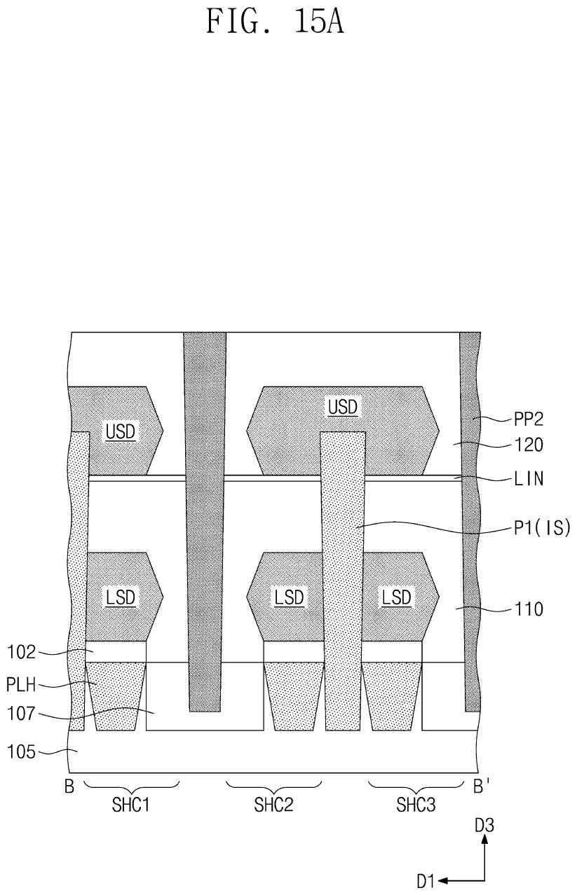

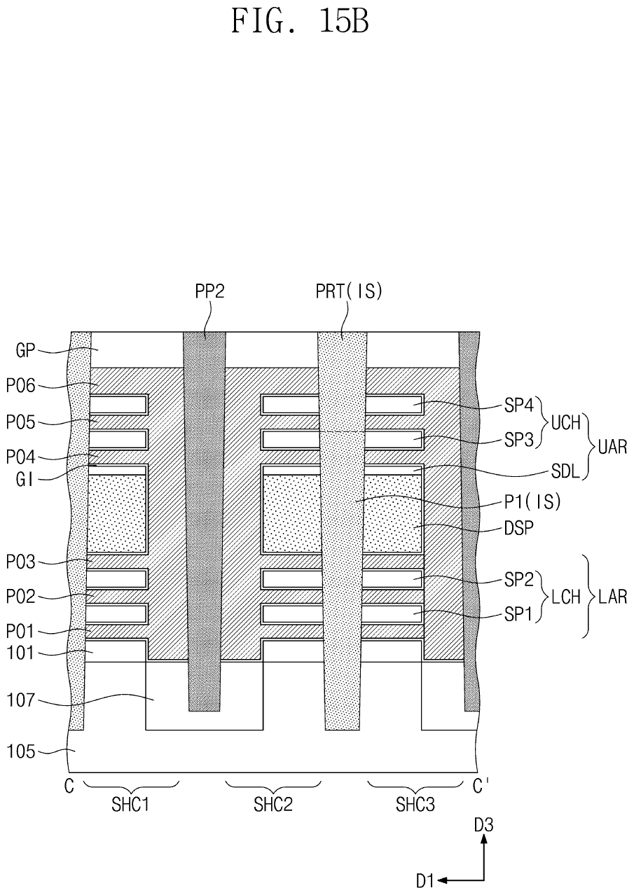

Referring to FIGS. 15A and 15B, a second sacrificial pattern PP2 may be formed at an opposite side of the lower and upper active regions LAR and UAR. The second sacrificial pattern PP2 may be spaced apart from the insulating structure IS, in the first direction D1, with one of the lower active regions LAR and one of the upper active regions UAR interposed therebetween. The second sacrificial pattern PP2 may penetrate the gate capping pattern GP, the second interlayer insulating layer 120, the liner layer LIN, the first interlayer insulating layer 110, and the gate electrode GE and may be extended into the device isolation layer 107. According to an embodiment of the inventive concept, the second sacrificial pattern PP2 may be formed between the first and second single height cells SHC1 and SHC2. The formation of the second sacrificial pattern PP2 may include forming a cutting mask pattern (not shown) on the gate capping pattern GP and the second interlayer insulating layer 120, forming a cutting hole exposing the device isolation layer 107, using the cutting mask pattern as an etch mask, and forming a sacrificial material in the cutting hole.

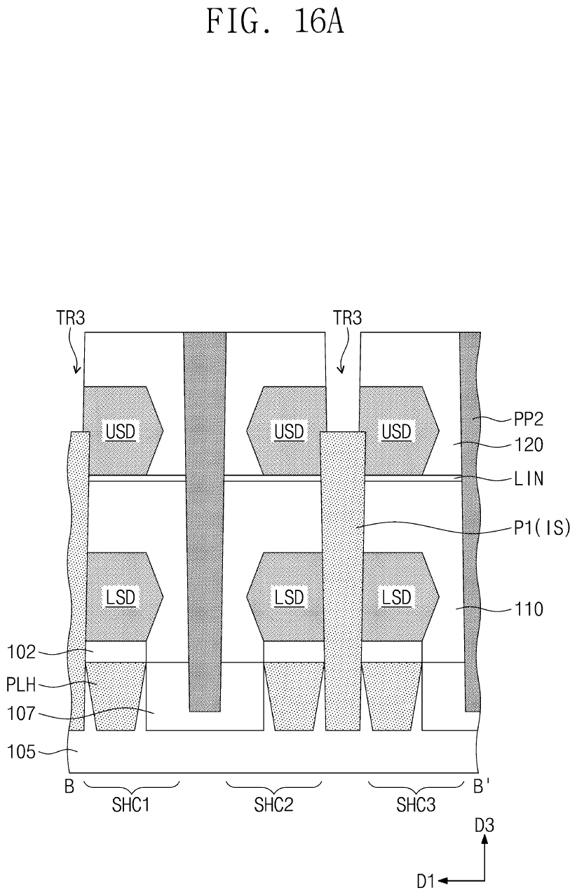

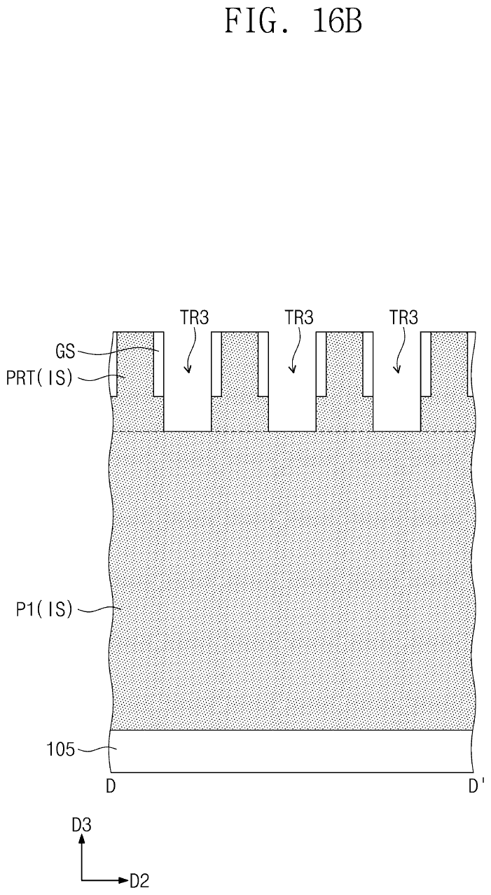

Referring to FIGS. 16A and 16B, third trenches TR3 may be formed on the first portion P1, which is placed between the upper source/drain patterns USD adjacent to each other in the first direction D1. In an embodiment, the formation of the third trenches TR3 may include forming a mask pattern (not shown) on the second interlayer insulating layer 120, etching the second interlayer insulating layer 120 using the mask pattern as an etch mask, etching a portion of the upper source/drain pattern USD using the mask pattern as an etch mask to expose a top surface of the first portion P1, and removing the mask pattern. As a result of the partial removal of the upper source/drain pattern USD, the upper source/drain pattern USD may be divided into two portions that are spaced apart from each other in the first direction D1.

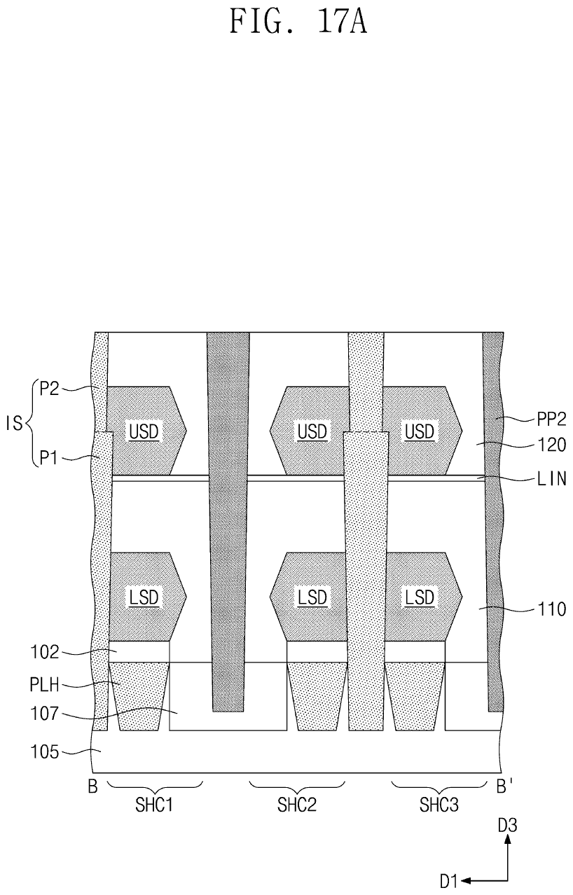

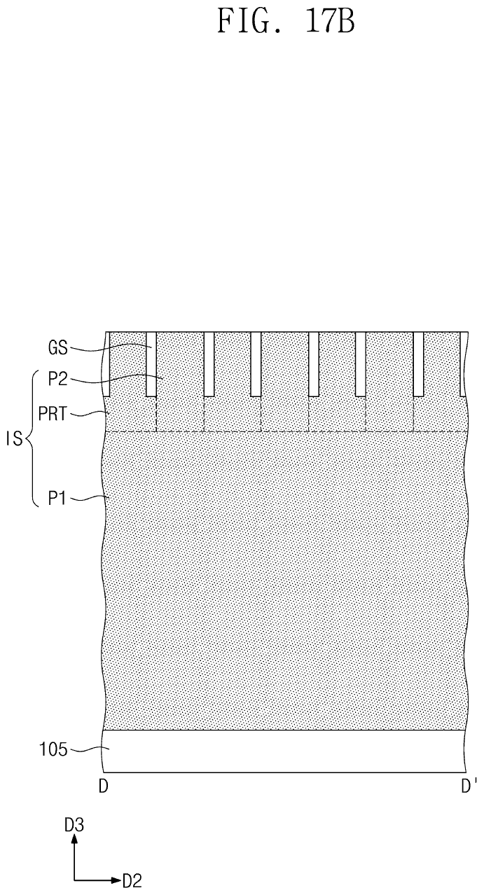

Referring to FIGS. 17A and 17B, the second portion P2 may be formed to fill the third trenches TR3. The insulating structure IS may include the first portion P1, the second portion P2, and the protruding portion PRT.

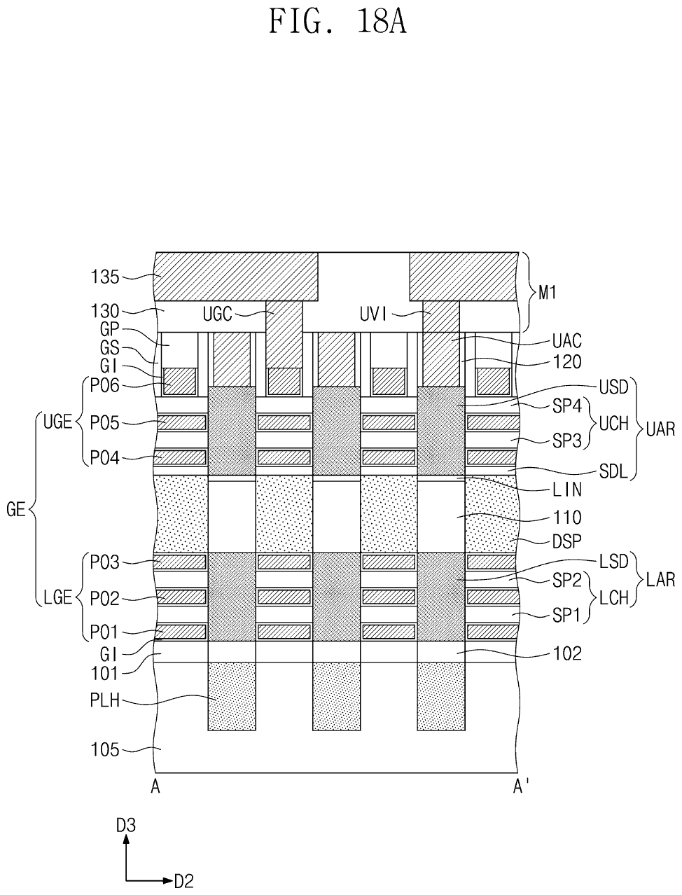

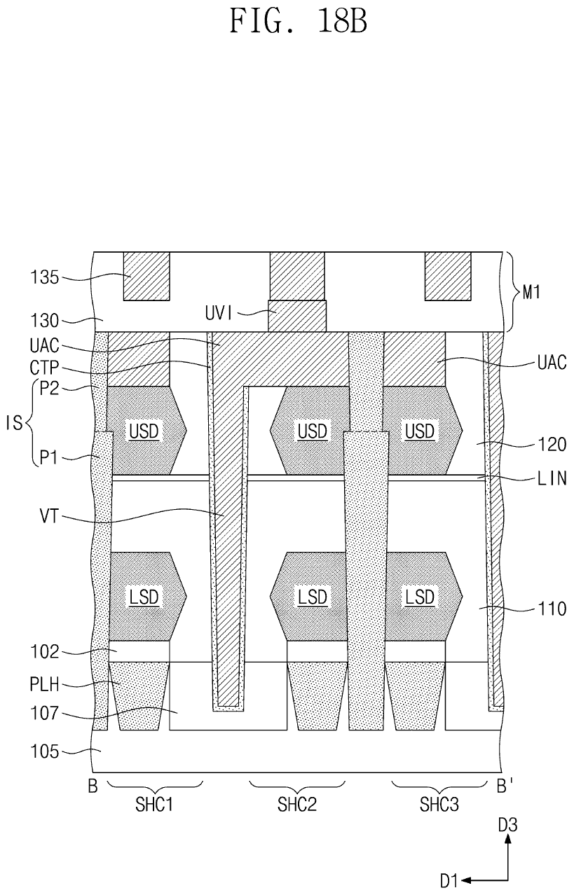

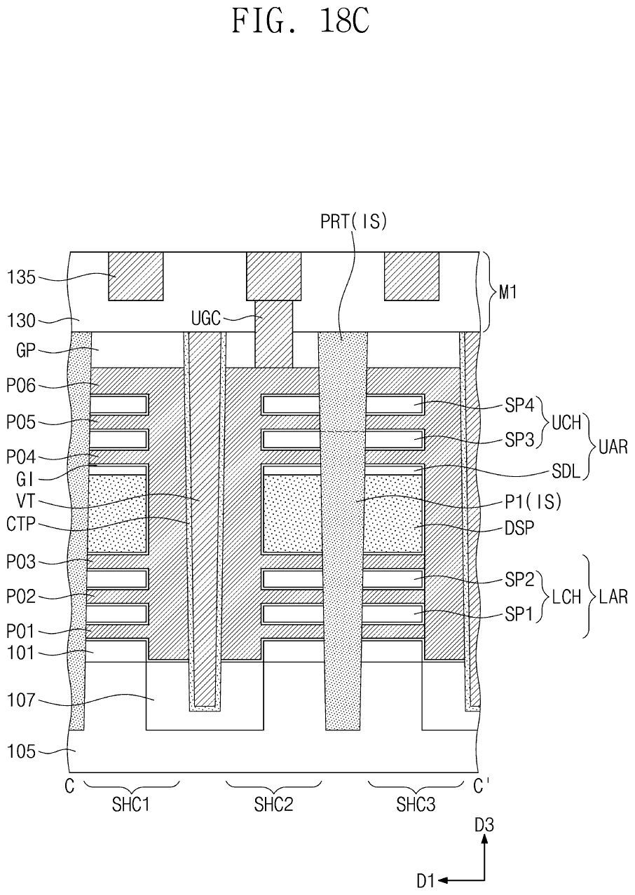

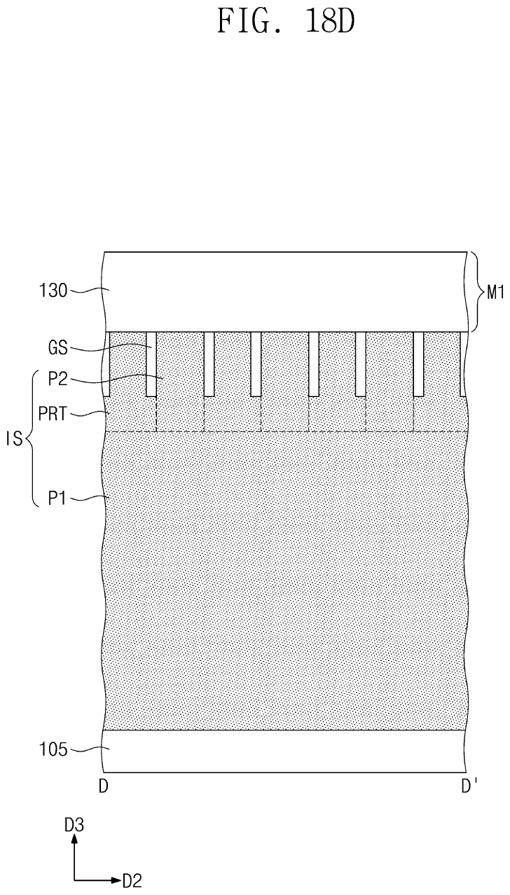

Referring to FIGS. 18A to 18D, the second sacrificial pattern PP2 may be selectively removed. The removal of the second sacrificial pattern PP2 may include a wet etching process using an etching solution capable of selectively etching the sacrificial material.

After the removal of the second sacrificial pattern PP2, the cutting pattern CTP may be formed in an exposed trench. The cutting pattern CTP may be formed to penetrate the gate capping pattern GP and the gate electrode GE and may be extended into the device isolation layer 107. The cutting pattern CTP may be formed by forming an insulating material to conformally cover the exposed trench.

The vertical via VT may be formed in the cutting pattern CTP. The formation of the vertical via VT may include filling the exposed trench, which is conformally covered with the insulating material, with a metallic material. For example, the metallic material may include a metallic material that is selected from the group consisting of copper (Cu), aluminum (Al), ruthenium (Ru), cobalt (Co), tungsten (W), and molybdenum (Mo).

The upper active contacts UAC may be formed to penetrate the second interlayer insulating layer 120 and may be coupled to the upper source/drain patterns USD, respectively. The upper active contact UAC may be extended in the first direction D1 to be in contact with an upper portion of the vertical via VT. For this, a portion of the cutting pattern CTP may be removed. The upper gate contact UGC may be formed to penetrate the second interlayer insulating layer 120 and the gate capping pattern GP and may be coupled to the gate electrode GE. For example, each of the upper active contact UAC and the upper gate contact UGC may be formed of or include a metallic material that is selected from the group consisting of copper (Cu), aluminum (Al), ruthenium (Ru), cobalt (Co), tungsten (W), and molybdenum (Mo).

The third interlayer insulating layer 130 may be formed to cover the second interlayer insulating layer 120. The first metal layer M1 including the upper interconnection lines 135 may be formed in the third interlayer insulating layer 130. The upper vias UVI may be formed to electrically connect the first metal layer M1 to the gate contacts GC and the upper active contacts UAC. A BEOL layer including additional metal layers (e.g., M2, M3, M4, and so forth) may be formed on the first metal layer M1.

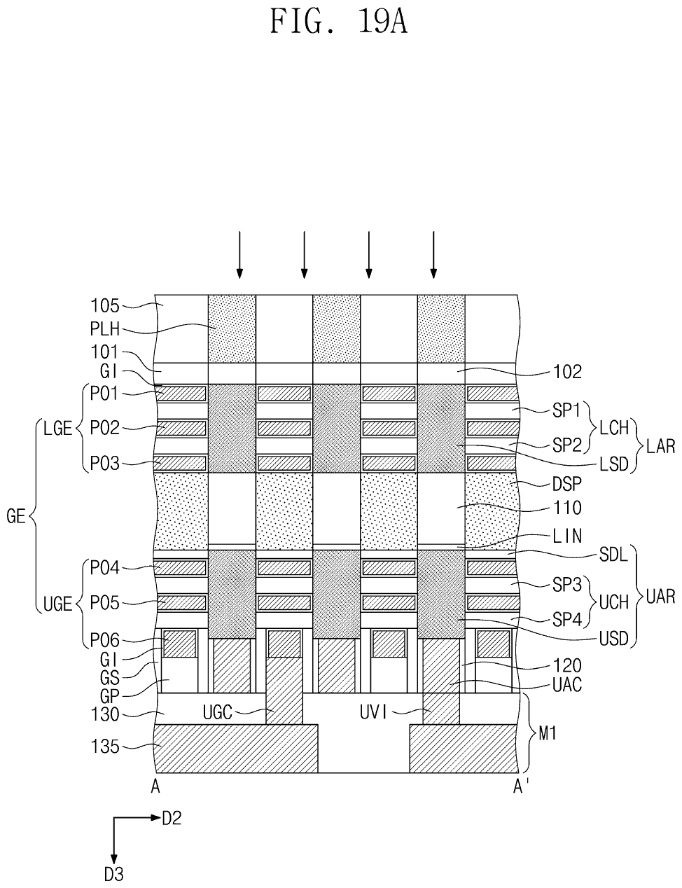

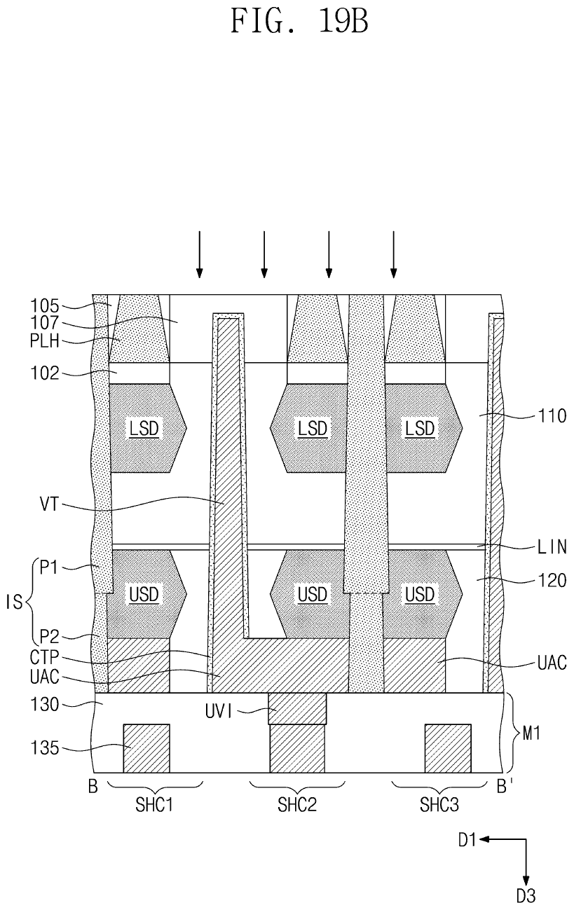

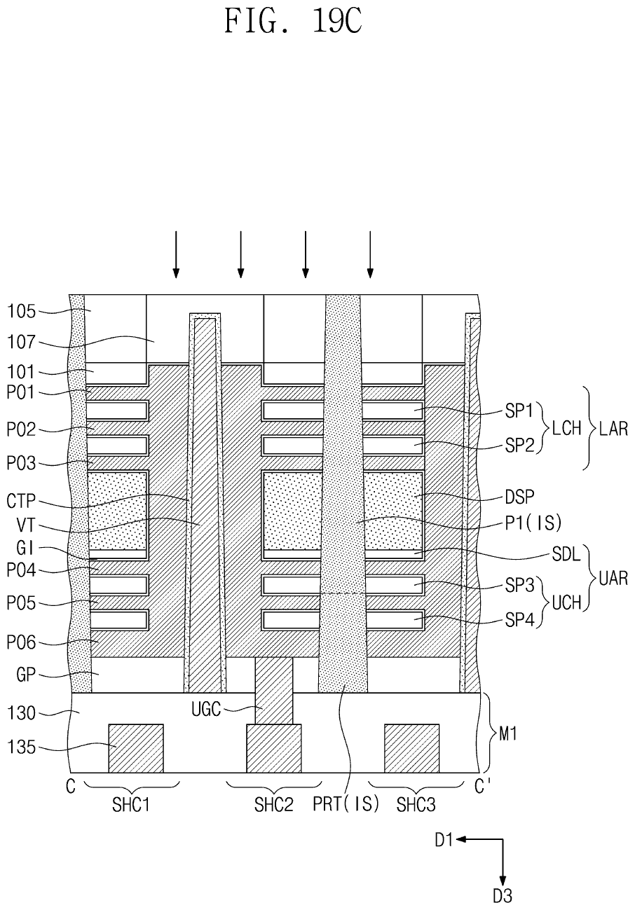

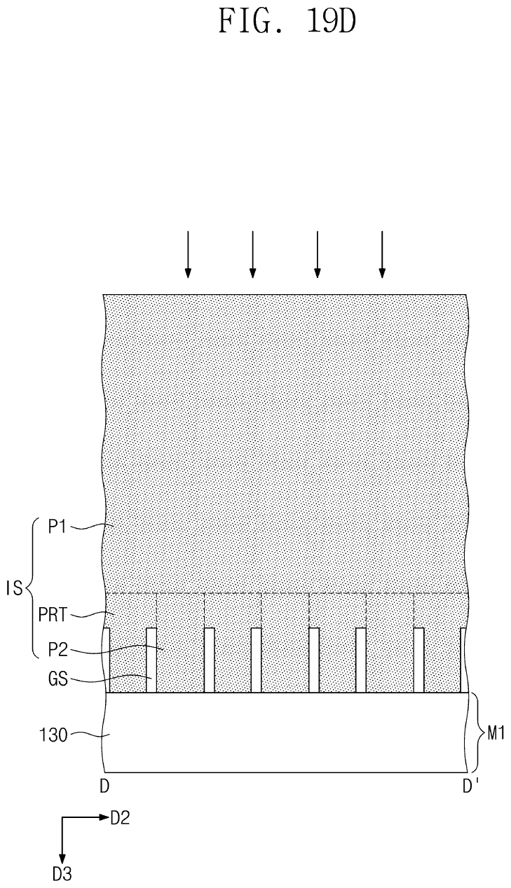

Referring to FIGS. 19A to 19D, the semiconductor substrate 105 may be inverted such that a rear surface of the semiconductor substrate 105 is exposed to the outside. An etching process may be performed on the rear surface of the semiconductor substrate 105 to reduce a height of the semiconductor substrate 105. A planarization process may be performed on the rear surface of the semiconductor substrate 105 to expose top surfaces of the sacrificial contact patterns PLH.

Referring back to FIGS. 4A to 4D, the sacrificial contact pattern PLH may be replaced with the lower active contact LAC. In detail, the sacrificial contact pattern PLH may be selectively removed. An etching process may be further performed on a region, which is formed by removing the sacrificial contact pattern PLH, to expose the lower source/drain pattern LSD. The lower active contact LAC may be formed to be coupled to the exposed lower source/drain pattern LSD. The lower active contact LAC may be formed in a self-aligned manner using the sacrificial contact pattern PLH. The lower active contact LAC may be extended in the first direction D1 and may be in contact with a lower portion of the vertical via VT. For this, a portion of the cutting pattern CTP may be removed.

The semiconductor substrate 105 may be replaced with the substrate 100. The substrate 100 may be an insulating substrate including a silicon-based insulating material (e.g., silicon oxide and/or silicon nitride). In an embodiment, the semiconductor substrate 105 may not be replaced with the substrate 100.

The lower interlayer insulating layer 200 may be formed on the substrate 100. The back-side metal layer BSM may be formed in the lower interlayer insulating layer 200. The back-side metal layer BSM may include the lower interconnection lines 235. In addition, the lower vias LVI may be formed to electrically connect the back-side metal layer BSM to the lower active contact LAC and the lower interconnection lines 235. Back-side metal layers may be additionally formed on the back-side metal layer BSM. In an embodiment, the back-side metal layers may include a power delivery network.

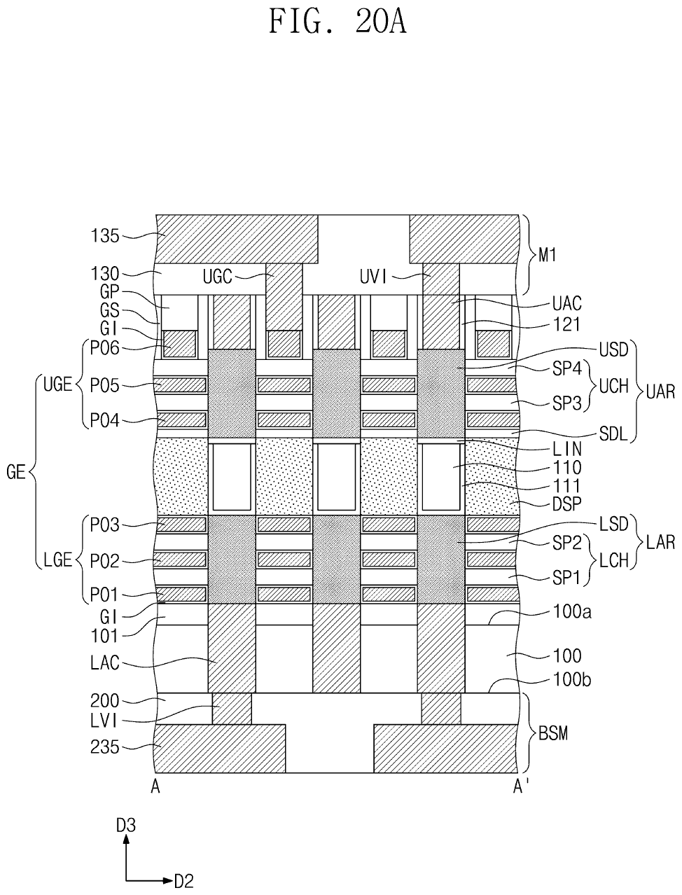

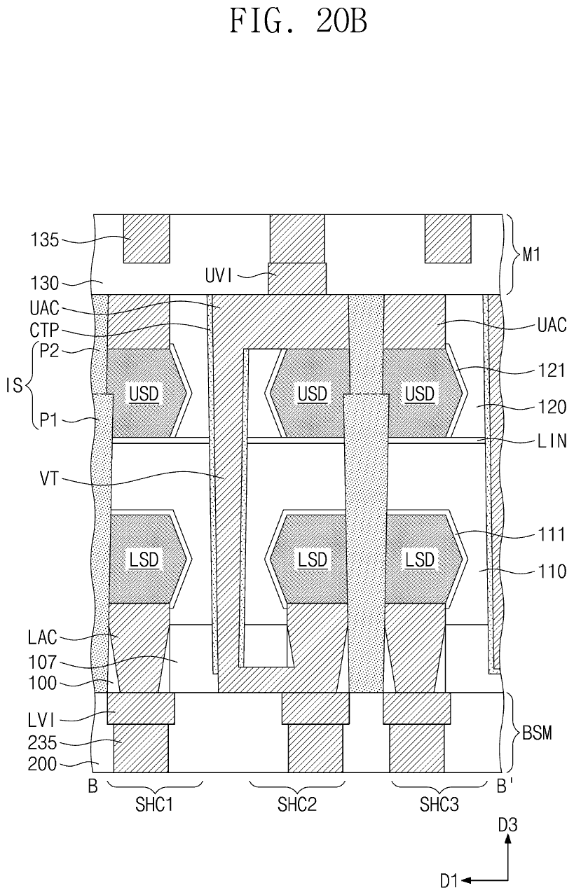

FIGS. 20A and 20B are sectional views, which are respectively taken along lines A-A′ and B-B′ of FIG. 3. For concise description, a previously described element may be identified by the same reference number without repeating an overlapping description thereof.

Referring to FIGS. 20A and 20B, a first insulating layer 111 may be provided on the lower source/drain patterns LSD. The first insulating layer 111 may be a single insulating layer or a plurality of insulating layers. A second insulating layer 121 may be provided on the upper source/drain pattern USD. The second insulating layer 121 may be a single insulating layer or a plurality of insulating layers.

In the three-dimensional semiconductor device according to an embodiment of the inventive concept, a cutting pattern and an insulating structure may be respectively provided at opposite sides of a logic cell. A width of the insulating structure may be larger at its bottom level than at its top level. For example, the width of the insulating structure may be discontinuously changed at a boundary between upper and lower portions thereof. Since the upper and lower portions of the insulating structure are separately and sequentially formed, it may be possible to prevent a short circuit issue from occurring in a process of forming the insulating structure. In some examples, the stepwise surface of the insulating structure may be formed via a two-step process, thereby preventing short circuit issues that may occur when the insulating structure is formed via a single process. Accordingly, the disclosed semiconductor device and fabrication methods can improve over other semiconductor devices by preventing or reducing short circuits. In addition, a vertical via may be formed in the cutting pattern, and in this case, it may be possible to reduce the width of the insulating structure and to increase the integration density of the logic cell. Furthermore, since the upper portion of the insulating structure is formed after forming a source/drain pattern, the source/drain pattern may be easily grown and may be formed to have an increased area. Accordingly, it may be possible to reduce a process difficulty in a subsequent step of forming a contact structure. As a result, the reliability and electrical characteristics of the three-dimensional semiconductor device may be improved using the disclosed semiconductor device and fabrication methods.

While example embodiments of the inventive concept have been particularly shown and described, it will be understood by one of ordinary skill in the art that variations in form and detail may be made therein without departing from the spirit and scope of the attached claims.

What is claimed is:

1. A three-dimensional semiconductor device, comprising:
a lower active region on a substrate, the lower active region comprising a lower channel pattern and a lower source/drain pattern connected to the lower channel pattern;
an upper active region on the lower active region, the upper active region comprising an upper channel pattern and an upper source/drain pattern connected to the upper channel pattern;
a gate electrode disposed on the lower and upper channel patterns and extended in a first direction; and
an insulating structure disposed at a side of the lower and upper active regions and extended in a second direction, the first and second directions being parallel to a top surface of the substrate and crossing each other,
wherein:
the insulating structure comprises a first portion, which is adjacent to the lower active region, and a second portion, which is provided on the first portion and is adjacent to the upper active region, and
a side surface of the insulating structure has a stepwise structure at a boundary between the first portion and the second portion.

2. The three-dimensional semiconductor device of claim 1, wherein the boundary between the first and second portions is located at a level that is higher than a bottom surface of the upper source/drain pattern and is lower than a top surface of the upper source/drain pattern.

3. The three-dimensional semiconductor device of claim 2, wherein:
the first portion of the insulating structure has a first width,
the second portion of the insulating structure has a second width, and
at the boundary between the first and second portions, the first width is larger than the second width.

4. The three-dimensional semiconductor device of claim 3, wherein the first width and the second width increase as a distance from the top surface of the substrate increases in a vertical direction perpendicular to the top surface of the substrate.

5. The three-dimensional semiconductor device of claim 2, wherein:
the insulating structure further comprises a third portion between the first and second portions,
the first portion has a first width, the first width being variable,
the second portion has a second width, the second width being variable,
the third portion has a third width, and
the third width is smaller than a largest value of the first width and is larger than a smallest value of the second width.

6. The three-dimensional semiconductor device of claim 5, wherein a side surface of the third portion is curved, and
the third width decreases as a distance from the first portion increases and as a distance to the second portion decreases.

7. The three-dimensional semiconductor device of claim 2, wherein a center line of the first portion and a center line of the second portion are offset from each other in the first direction, when viewed in a plan view.

8. The three-dimensional semiconductor device of claim 2, further comprising an insulating pattern interposed between the first portion and the second portion,
wherein the insulating pattern comprises a material having an etch selectivity different from the insulating structure.

9. The three-dimensional semiconductor device of claim 8, wherein the insulating pattern is extended from a bottom surface of the second portion along a side surface of the second portion in a vertical direction perpendicular to the top surface of the substrate.

10. The three-dimensional semiconductor device of claim 2, wherein a top surface of the insulating structure is located at a level higher than a top surface of the upper source/drain pattern and a top surface of the gate electrode.

11. The three-dimensional semiconductor device of claim 2, further comprising:
a cutting pattern, which is disposed at an opposite side of the lower and upper active regions, is extended from the lower active region to the upper active region in a vertical direction perpendicular to the top surface of the substrate, and is extended in the second direction;
a lower active contact coupled to the lower source/drain pattern;
an upper active contact coupled to the upper source/drain pattern; and
a vertical via connecting the lower active contact to the upper active contact,
wherein the vertical via is provided to penetrate the cutting pattern.

12. The three-dimensional semiconductor device of claim 1, wherein the three-dimensional semiconductor device comprises one or more of a complementary field effect transistor (CFET), a stacked field effect transistor (SFET), or a three-dimensional (3D) field effect transistor (3D-FET).

13. A three-dimensional semiconductor device, comprising:
a lower active region on a substrate, the lower active region comprising a lower channel pattern and a lower source/drain pattern connected to the lower channel pattern;
an upper active region stacked on the lower active region, the upper active region comprising an upper channel pattern and an upper source/drain pattern connected to the upper channel pattern;
a gate electrode disposed on the lower and upper channel patterns and extended in a first direction; and
an insulating structure disposed at a side of the lower and upper active regions and extended in a second direction, the first and second directions being parallel to a top surface of the substrate and crossing each other,
wherein:
the insulating structure comprises a first portion, which is adjacent to the lower active region and a second portion, which is provided on the first portion and is adjacent to the upper active region,
a side surface of the first portion protrudes relative to a side surface of the second portion in the first direction, and
the first portion has a stepwise surface connecting the side surface of the first portion to the side surface of the second portion.

14. The three-dimensional semiconductor device of claim 13, wherein the stepwise surface is located at a level that is higher than a bottom surface of the upper source/drain pattern and is lower than a top surface of the upper source/drain pattern.

15. The three-dimensional semiconductor device of claim 14, wherein the insulating structure further comprises a third portion between the first and second portions,
the first portion has a first width, the first width being variable,
the second portion has a second width, the second width being variable,
the third portion has a third width, and
the third width is smaller than a largest value of the first width and is larger than a smallest value of the second width.

16. The three-dimensional semiconductor device of claim 15, wherein a side surface of the third portion is curved, and
the third width decreases as a distance from the first portion increases and as a distance to the second portion decreases.

17. The three-dimensional semiconductor device of claim 14, wherein a center line of the first portion and a center line of the second portion are offset from each other in the first direction, when viewed in a plan view.

18. The three-dimensional semiconductor device of claim 14, wherein a top surface of the insulating structure is located at a level that is higher than a top surface of the upper source/drain pattern and a top surface of the gate electrode.

19. A three-dimensional semiconductor device, comprising:
lower active regions spaced apart from each other in a first direction on a substrate, each of the lower active regions comprising lower channel patterns, which are spaced apart from each other in a second direction crossing the first direction, and lower source/drain patterns, which are connected to the lower channel patterns;
upper active regions stacked on the lower active regions, respectively, each of the upper active regions comprising upper channel patterns, which are spaced apart from each other in the second direction, and upper source/drain patterns, which are connected to the upper channel patterns;
gate electrodes disposed on the lower and upper channel patterns, respectively, the gate electrodes being extended in the first direction and being spaced apart from each other in the second direction;
an insulating structure disposed between the lower active regions and the upper active regions and extended from the lower active regions to the upper active regions in a vertical direction;
a cutting pattern, which is spaced apart from the insulating structure, with one of the lower active regions and one of the upper active regions interposed therebetween, in the first direction and is extended from the lower active regions to the upper active regions in the vertical direction; and
a vertical via penetrating the cutting pattern in the vertical direction, wherein:
the insulating structure comprises a first portion, which is adjacent to the lower active region, and a second portion, which is provided on the first portion and is adjacent to the upper active region,
a side surface of the insulating structure has a boundary between the first and second portions, the boundary having a stepwise structure, and
the boundary is located at a level that is higher than bottom surfaces of the upper source/drain patterns and is lower than top surfaces of the upper source/drain patterns.

20. The three-dimensional semiconductor device of claim 19, wherein the first portion of the insulating structure has a first width,
the second portion of the insulating structure has a second width, and
at the boundary between the first and second portions, the first width is larger than the second width.
